(19) United States
(12) Patent Application Publication
(10) Pub. No.: US 2025/0006731 A1
(43) Pub. Date: Jan. 2, 2025

(54) HIGH VOLTAGE TRANSISTOR STRUCTURE AND METHODS OF FORMATION

(71) Applicant: Taiwan Semiconductor Manufacturing Company, Ltd., Hsinchu (TW)

(72) Inventors: Kau-Chu LIN, Taichung City (TW); Chan-yu HUNG, Tainan City (TW); Fei-Yun CHEN, Hinchu (TW)

(21) Appl. No.: 18/345,844

(22) Filed: Jun. 30, 2023

(51) Int. Cl. H01L 27/088; H01L 21/8234; H01L 29/66; H01L 29/78

(52) U.S. Cl. CPC H01L 27/0886; H01L 21/823418; H01L 21/823431; H01L 29/66492; H01L 29/66795; H01L 29/7833; H01L 29/7851

(57) ABSTRACT

A high voltage transistor may include a plurality of source/drain regions, a gate structure, and a gate oxide layer that enables the gate structure to selectively control a channel region between the source/drain regions. The gate oxide layer may extend laterally outward toward one or more of the plurality of source/drain regions such that at least a portion of the gate oxide layer is not under the gate structure. The gate oxide layer extending laterally outward from under the gate structure enables the gate oxide layer to be used as a self-aligned structure for forming the source/drain regions of the high voltage transistor. In particular, the gate oxide layer extending laterally outward from under the gate structure enables the gate oxide layer to be used to form the source/drain regions at a greater spacing from the gate structure without the use of additional implant masks when forming the source/drain regions.

### BACKGROUND

A high voltage transistor includes a transistor that is configured to operate at high voltages (e.g., a high gate voltage, a high drain voltage) relative to other types of transistors. High voltage transistors may be included in level shifter circuits, power generation circuits, and/or other types of high voltage circuits.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a diagram of an example environment in which systems and/or methods described herein may be implemented.

FIG. 2 is a diagram of an example semiconductor device described herein.

FIGS. 3A-3C are diagrams of an example implementation of a high voltage transistor described herein.

FIGS. 4A and 4B are diagrams of example tuning parameters for a high voltage transistor described herein.

FIGS. 5A-5M are diagrams of an example implementation described herein.

FIG. 6 is a diagram of example components of a device described herein.

FIG. 7 is a flowchart of an example process associated with forming a semiconductor device described herein.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

A high voltage transistor may include a plurality of source/drain regions, a gate structure, and a gate oxide layer (e.g., a high temperature oxide (HTO) and/or another type of gate oxide) that enables the gate structure to selectively control a channel region between the source/drain regions. A source/drain region may refer to a source or a drain, individually or collectively dependent upon the context. Sidewall spacers may be included on the sidewalls of the gate structure to electrically isolate the gate structure from other structures near the high voltage transistor.

As the sizes of structures and/or layers in a semiconductor are reduced in the advancement of semiconductor processing nodes, the spacing between these structures and/or layers may also be reduced. The reduced size and/or spacing of the structures and/or layers may result in unwanted side effects such as parasitic capacitance and/or current leakage, among other examples. In a high voltage transistor, reduced structure and/or layers sizes may result in reduced spacing between a gate structure of the high voltage transistor and a source/drain region of the high voltage transistor. The reduced spacing may result in gate induced drain leakage (GIDL). GIDL occurs when carrier depletion in the channel of the high voltage transistor causes a depletion region of the channel to encroach on the source/drain region when the gate structure is activated. High voltage transistors are particularly susceptible to GIDL in that high source/drain voltages induce greater carrier depletion in the channel and greater encroachment of the depletion region on the source/drain region. GIDL in the high voltage transistor may increase stand-by power consumption of the high voltage transistor (e.g., power consumption when the high voltage transistor is switched off) and/or may increase heat dissipation in the high voltage transistor, which may reduce the operational lifespan of the high voltage transistor.

In some implementations described herein, a semiconductor device may include a high voltage transistor. The high voltage transistor may include a plurality of source/drain regions, a gate structure, and a gate oxide layer that enables the gate structure to selectively control a channel region between the source/drain regions. The gate oxide layer may extend laterally outward toward one or more of the plurality of source/drain regions such that at least a portion of the gate oxide layer is not under the gate structure. The gate oxide layer extending laterally outward from under the gate structure enables the gate oxide layer to be used as a self-aligned structure for forming the source/drain regions of the high voltage transistor. In particular, the gate oxide layer extending laterally outward from under the gate structure enables the gate oxide layer to be used to form the source/drain regions at a greater spacing from the gate structure than if the gate oxide layer extending were fully contained within a perimeter of the gate structure. This results in less depletion region encroachment onto the source/drain regions and, therefore, reduced (or no) GIDL in the high voltage transistor than if the gate oxide layer extending were fully contained within a perimeter of the gate structure. The reduced GIDL in the high voltage transistor may reduce stand-by power consumption of the high voltage transistor and/or may reduce heat dissipation in the high voltage transistor, which may increase the operational lifespan of the high voltage transistor.

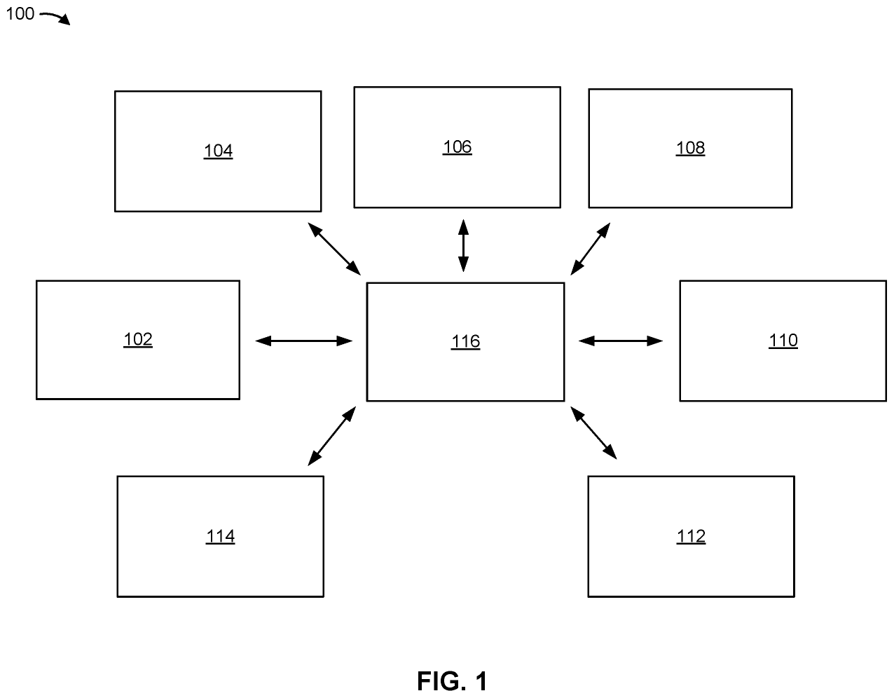

FIG. 1 is a diagram of an example environment 100 in which systems and/or methods described herein may be implemented. As shown in FIG. 1, environment 100 may include a plurality of semiconductor processing tools 102-114 and a wafer/die transport tool 116. The plurality of semiconductor processing tools 102-114 may include a deposition tool 102, an exposure tool 104, a developer tool 106, an etch tool 108, a planarization tool 110, a plating tool 112, an ion implantation tool 114, and/or another type of semiconductor processing tool. The tools included in example environment 100 may be included in a semiconductor clean room, a semiconductor foundry, a semiconductor processing facility, and/or manufacturing facility, among other examples.

The deposition tool 102 is a semiconductor processing tool that includes a semiconductor processing chamber and one or more devices capable of depositing various types of materials onto a substrate. In some implementations, the deposition tool 102 includes a spin coating tool that is capable of depositing a photoresist layer on a substrate such as a wafer. In some implementations, the deposition tool 102 includes a chemical vapor deposition (CVD) tool such as a plasma enhanced CVD (PECVD) tool, a low pressure CVD (LPCVD) tool, a high-density plasma CVD (HDP-CVD) tool, a sub-atmospheric CVD (SACVD) tool, an atomic layer deposition (ALD) tool, a plasma-enhanced atomic layer deposition (PEALD) tool, or another type of CVD tool. In some implementations, the deposition tool 102 includes a physical vapor deposition (PVD) tool, such as a sputtering tool or another type of PVD tool. In some implementations, the example environment 100 includes a plurality of types of deposition tools 102.

The exposure tool 104 is a semiconductor processing tool that is capable of exposing a photoresist layer to a radiation source, such as an ultraviolet light (UV) source (e.g., a deep UV light source, an extreme UV light (EUV) source, and/or the like), an x-ray source, an electron beam (e-beam) source, and/or the like. The exposure tool 104 may expose a photoresist layer to the radiation source to transfer a pattern from a photomask to the photoresist layer. The pattern may include one or more semiconductor device layer patterns for forming one or more semiconductor devices, may include a pattern for forming one or more structures of a semiconductor device, may include a pattern for etching various portions of a semiconductor device, and/or the like. In some implementations, the exposure tool 104 includes a scanner, a stepper, or a similar type of exposure tool.

The developer tool 106 is a semiconductor processing tool that is capable of developing a photoresist layer that has been exposed to a radiation source to develop a pattern transferred to the photoresist layer from the exposure tool 104. In some implementations, the developer tool 106 develops a pattern by removing unexposed portions of a photoresist layer. In some implementations, the developer tool 106 develops a pattern by removing exposed portions of a photoresist layer. In some implementations, the developer tool 106 develops a pattern by dissolving exposed or unexposed portions of a photoresist layer through the use of a chemical developer.

The etch tool 108 is a semiconductor processing tool that is capable of etching various types of materials of a substrate, wafer, or semiconductor device. For example, the etch tool 108 may include a wet etch tool, a dry etch tool, and/or the like. In some implementations, the etch tool 108 includes a chamber that is filled with an etchant, and the substrate is placed in the chamber for a particular time period to remove particular amounts of one or more portions of the substrate. In some implementations, the etch tool 108 may etch one or more portions of the substrate using a plasma etch or a plasma-assisted etch, which may involve using an ionized gas to isotropically or directionally etch the one or more portions.

The planarization tool 110 is a semiconductor processing tool that is capable of polishing or planarizing various layers of a wafer or semiconductor device. For example, a planarization tool 110 may include a chemical mechanical planarization (CMP) tool and/or another type of planarization tool that polishes or planarizes a layer or surface of deposited or plated material. The planarization tool 110 may polish or planarize a surface of a semiconductor device with a combination of chemical and mechanical forces (e.g., chemical etching and free abrasive polishing). The planarization tool 110 may utilize an abrasive and corrosive chemical slurry in conjunction with a polishing pad and retaining ring (e.g., typically of a greater diameter than the semiconductor device). The polishing pad and the semiconductor device may be pressed together by a dynamic polishing head and held in place by the retaining ring. The dynamic polishing head may rotate with different axes of rotation to remove material and even out any irregular topography of the semiconductor device, making the semiconductor device flat or planar.

The plating tool 112 is a semiconductor processing tool that is capable of plating a substrate (e.g., a wafer, a semiconductor device, and/or the like) or a portion thereof with one or more metals. For example, the plating tool 112 may include a copper electroplating device, an aluminum electroplating device, a nickel electroplating device, a tin electroplating device, a compound material or alloy (e.g., tin-silver, tin-lead, and/or the like) electroplating device, and/or an electroplating device for one or more other types of conductive materials, metals, and/or similar types of materials.

The ion implantation tool 114 is a semiconductor processing tool that is capable of implanting ions into a substrate. The ion implantation tool 114 may generate ions in an arc chamber from a source material such as a gas or a solid. The source material may be provided into the arc chamber, and an arc voltage is discharged between a cathode and an electrode to produce a plasma containing ions of the source material. One or more extraction electrodes may be used to extract the ions from the plasma in the arc chamber and accelerate the ions to form an ion beam. The ion beam may be directed toward the substrate such that the ions are implanted below the surface of the substrate.

The wafer/die transport tool 116 may be included in a cluster tool or another type of tool that includes a plurality of processing chambers, and may be configured to transport substrates and/or semiconductor devices between the plurality of processing chambers, to transport substrates and/or semiconductor devices between a processing chamber and a buffer area, to transport substrates and/or semiconductor devices between a processing chamber and an interface tool such as an equipment front end module (EFEM), and/or to transport substrates and/or semiconductor devices between a processing chamber and a transport carrier (e.g., a front opening unified pod (FOUP)), among other examples. In some implementations, a wafer/die transport tool 116 may be included in a multi-chamber (or cluster) deposition tool 102, which may include a pre-clean processing chamber (e.g., for cleaning or removing oxides, oxidation, and/or other types of contamination or byproducts from a substrate and/or semiconductor device) and a plurality of types of deposition processing chambers (e.g., processing chambers for depositing different types of materials, processing chambers for performing different types of deposition operations).

In some implementations, one or more of the semiconductor processing tools 102-114 and/or the wafer/die transport tool 116 may perform one or more semiconductor processing operations described herein. For example, one or more of the semiconductor processing tools 102-114 and/or the wafer/die transport tool 116 may dope a substrate with a first dopant type to form a first doped region of a semiconductor device; may dope the substrate with a second dopant type to form a second doped region of the semiconductor device adjacent to the first doped region; may form an oxide layer over the first doped region and over the second doped region; may form, over the oxide layer, a gate structure of a high voltage transistor structure of the semiconductor device; may perform an etch operation to remove material from the oxide layer to form a gate oxide layer of the high voltage transistor structure, where the etch operation results in a portion of the gate oxide layer extending laterally outward from the gate structure; and/or may form a plurality of source/drain regions of the high voltage transistor structure using the gate oxide layer as a self-aligned pattern, among other examples.

As another example, one or more of the semiconductor processing tools 102-114 and/or the wafer/die transport tool 116 may form the plurality of source/drain regions by doping the substrate using the gate oxide layer as a self-aligned implantation mask. As another example, one or more of the semiconductor processing tools 102-114 and/or the wafer/die transport tool 116 may perform the etch operation such that gate oxide layer extends laterally outward from the gate structure by a distance that satisfies a threshold distance. As another example, one or more of the semiconductor processing tools 102-114 and/or the wafer/die transport tool 116 may perform a single sidewall spacer formation process to form a sidewall spacer on a sidewall of the gate structure prior to performing the etch operation. As another example, one or more of the semiconductor processing tools 102-114 and/or the wafer/die transport tool 116 may perform the single sidewall spacer formation process to form the sidewall spacer on the sidewall of the gate structure and to form another sidewall spacer on another gate structure of a low voltage fin field effect transistor (finFET) structure of the semiconductor device.

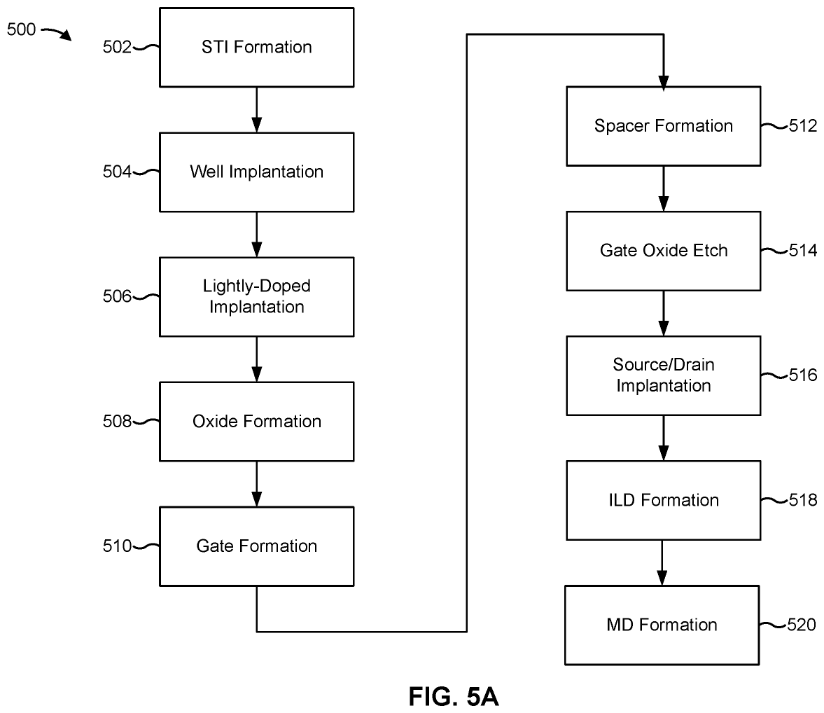

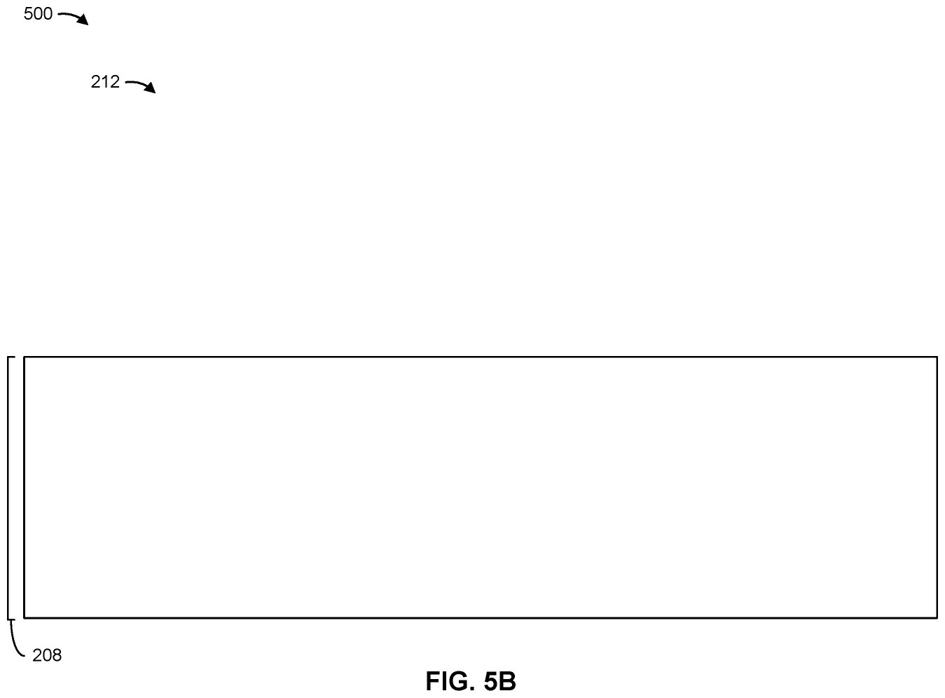

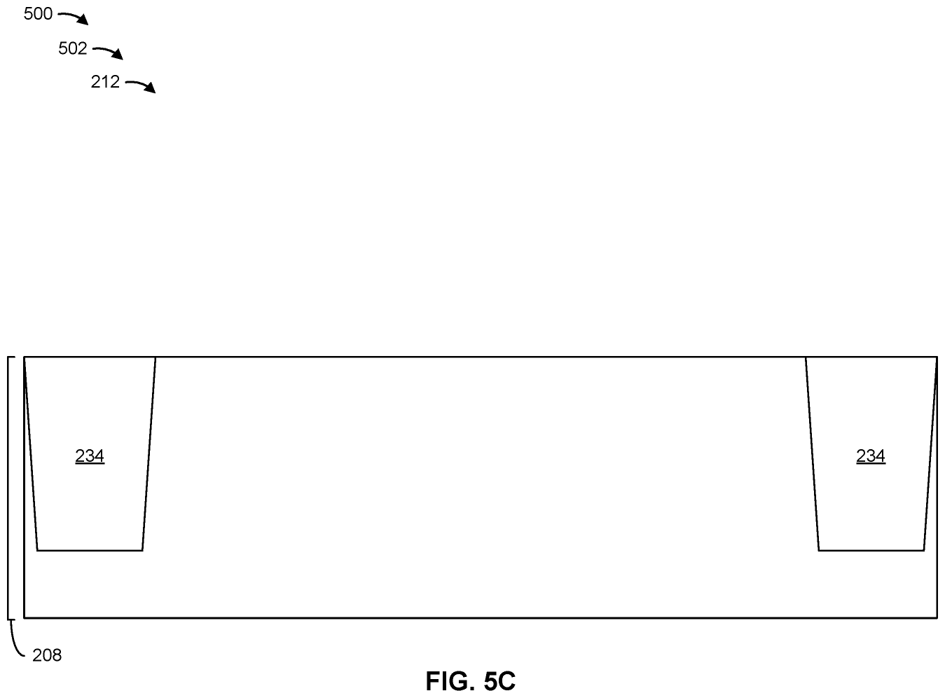

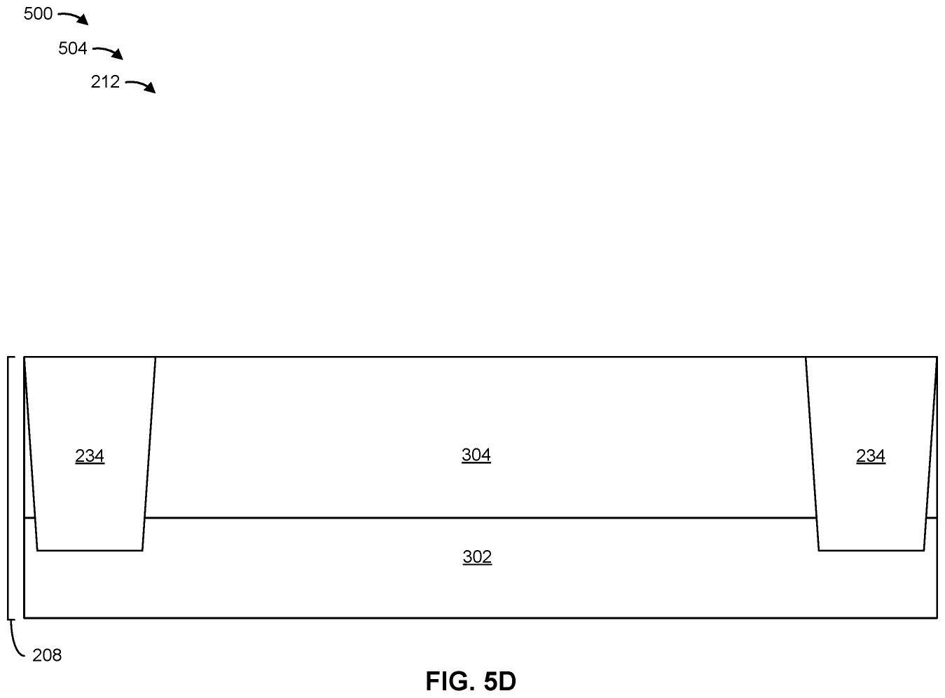

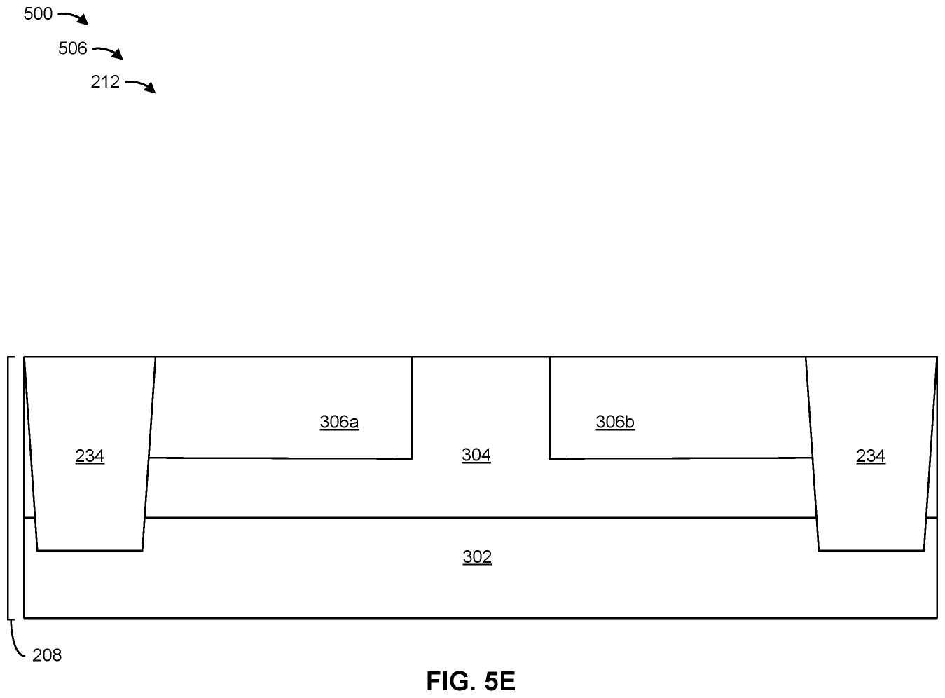

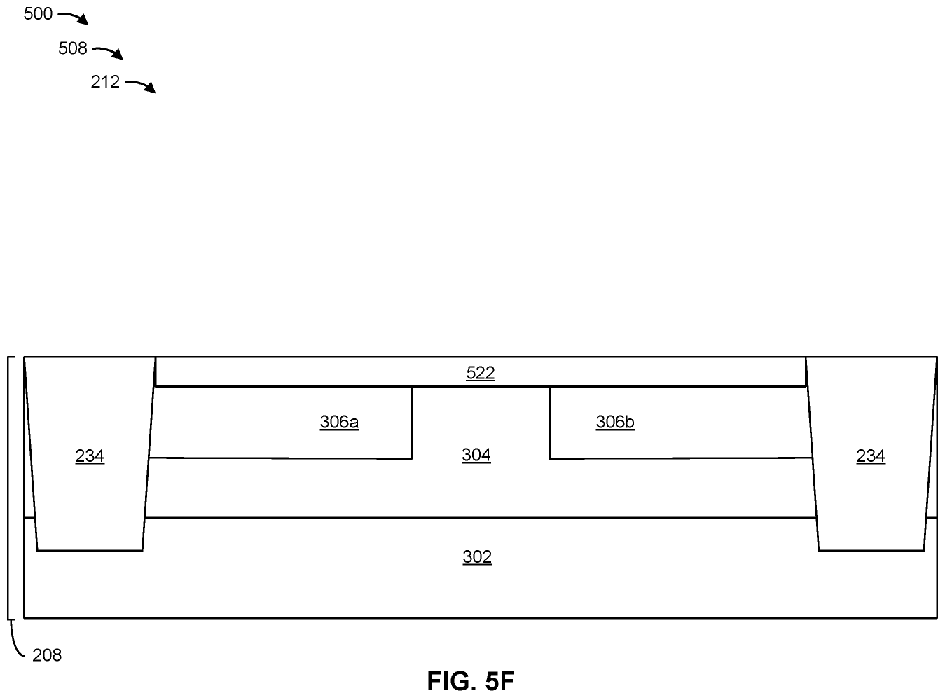

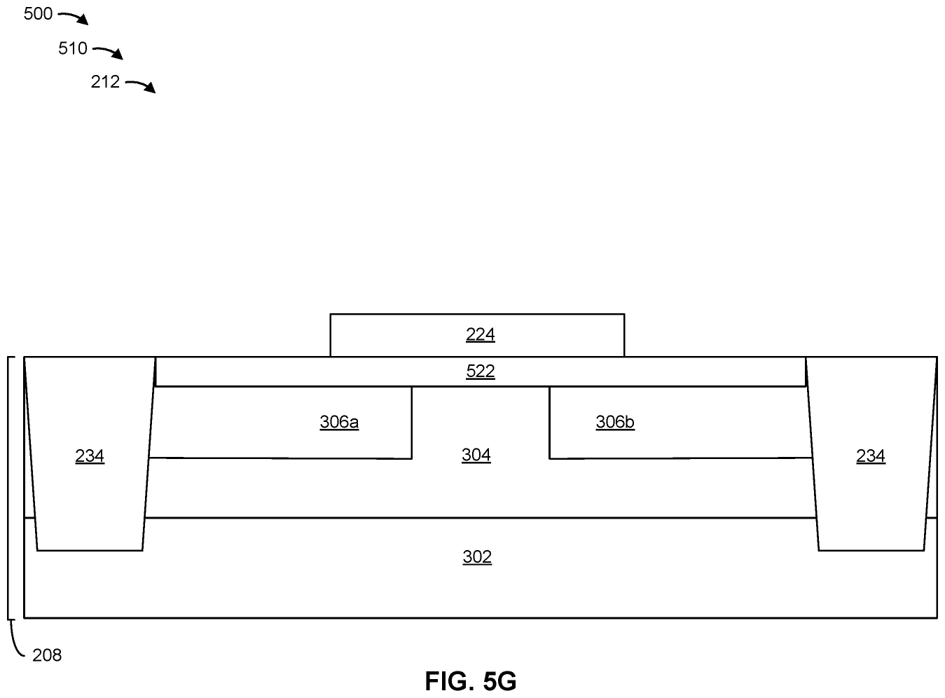

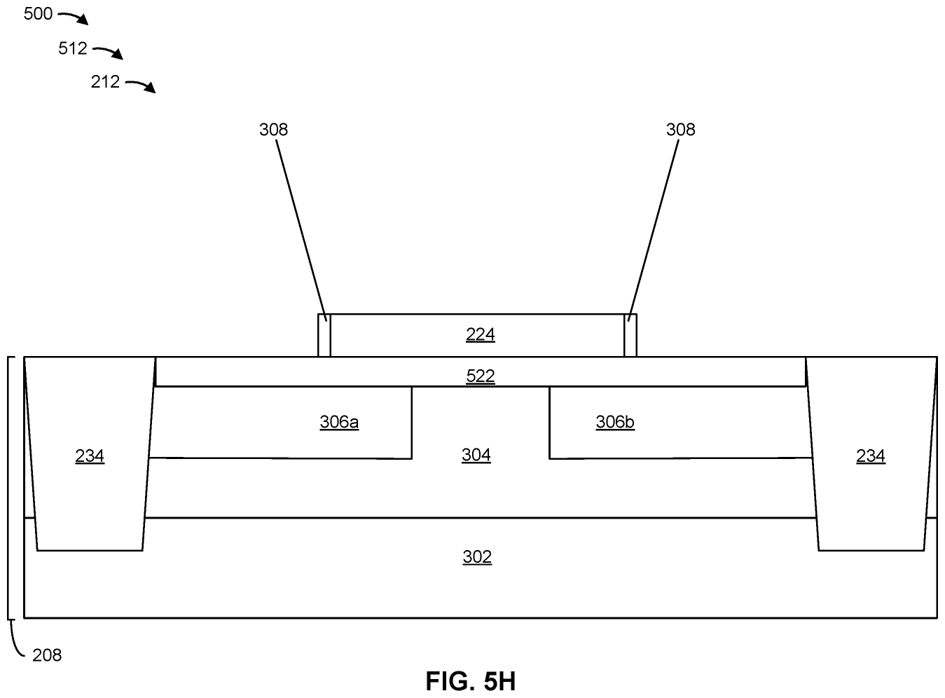

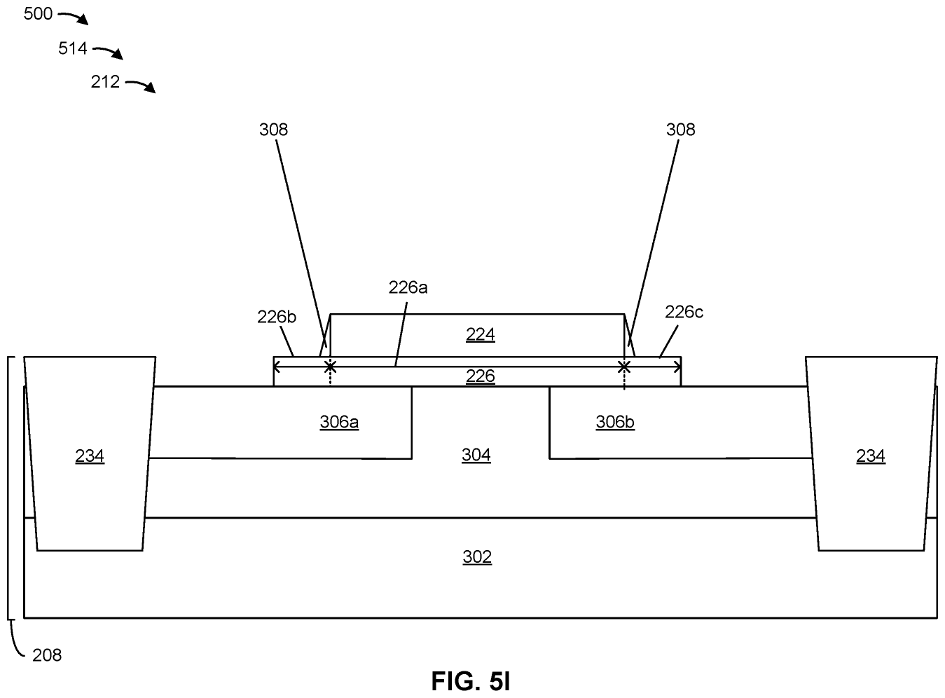

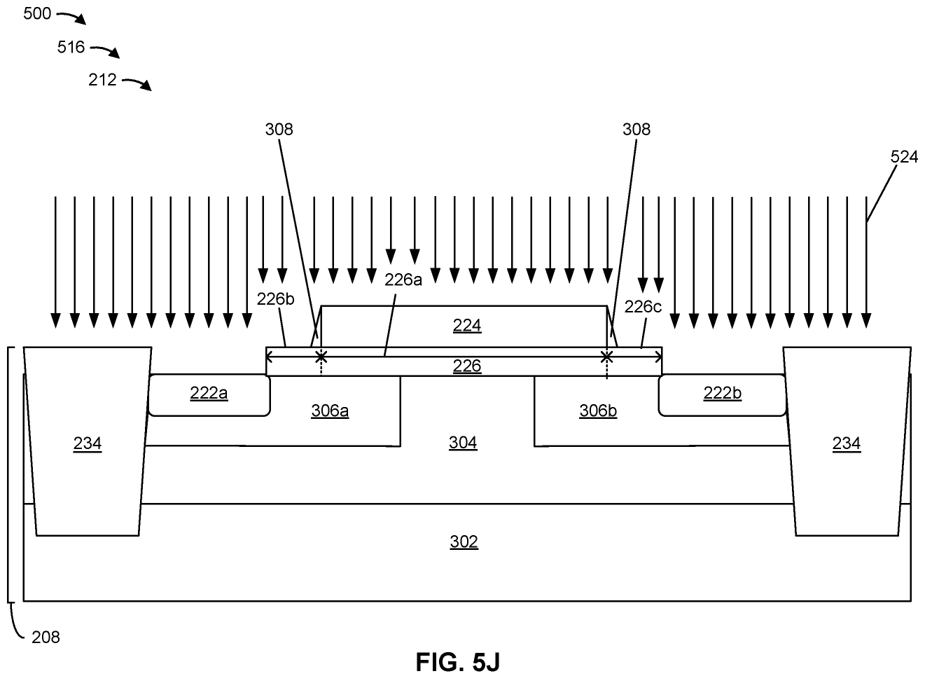

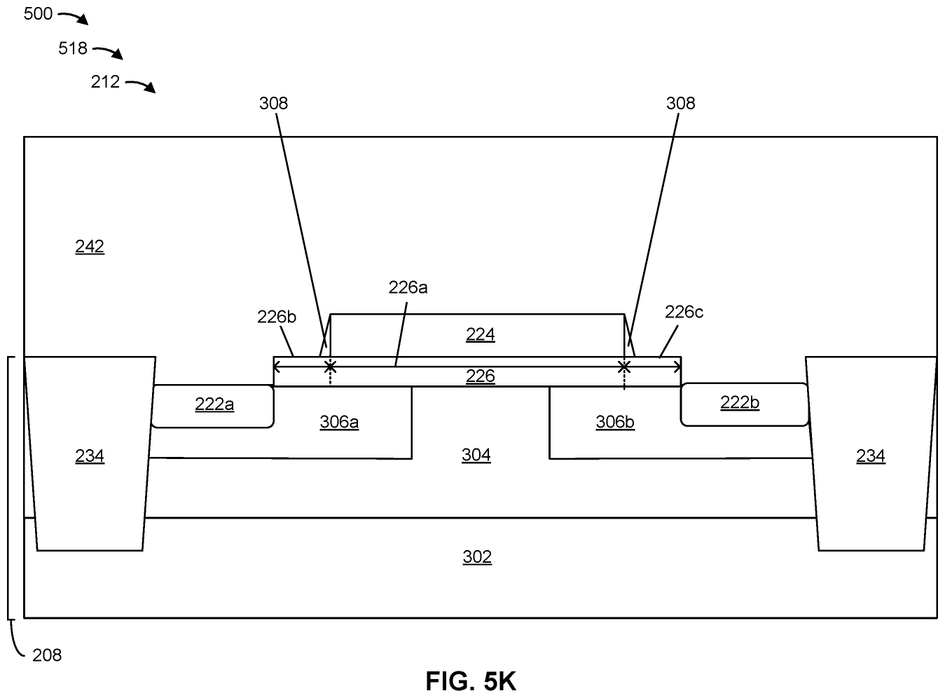

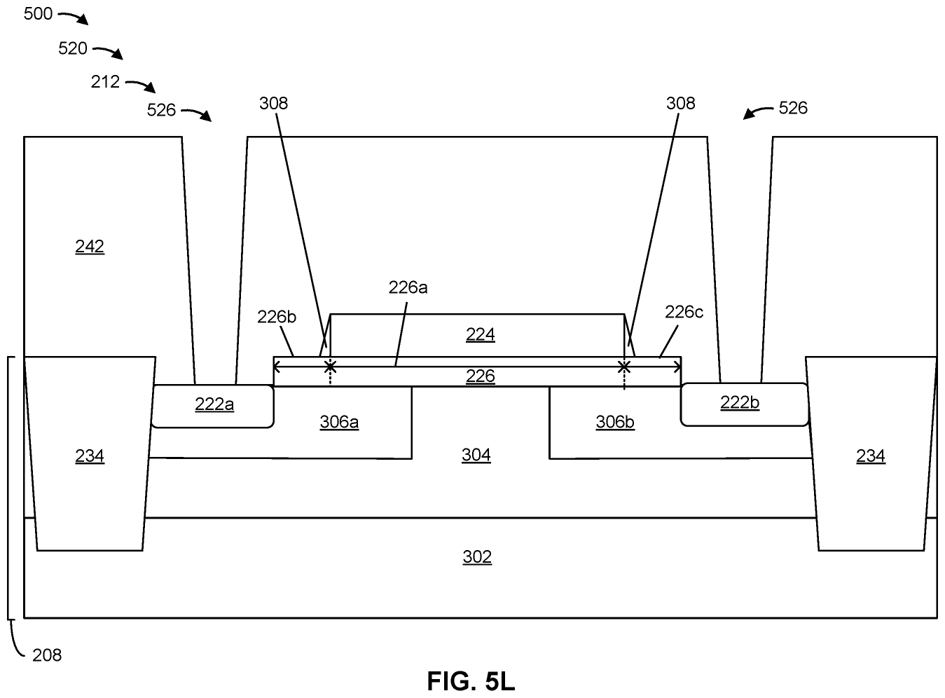

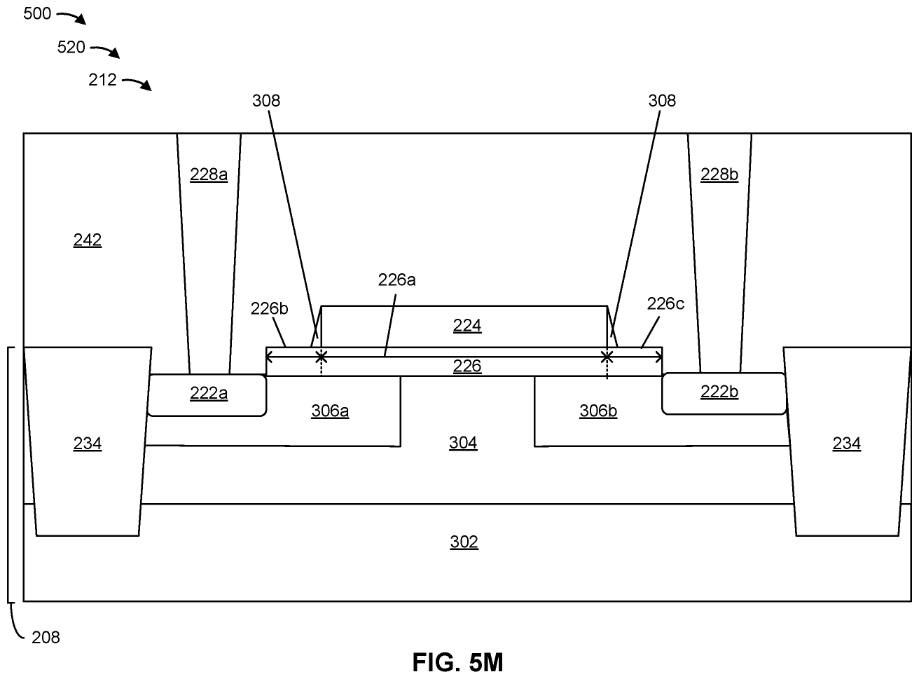

One or more of the semiconductor processing tools 102-114 and/or the wafer/die transport tool 116 may perform other semiconductor processing operations described herein, such as in connection with FIGS. 5A-5M and/or 7, among other examples.

The number and arrangement of devices shown in FIG. 1 are provided as one or more examples. In practice, there may be additional devices, fewer devices, different devices, or differently arranged devices than those shown in FIG. 1. Furthermore, two or more devices shown in FIG. 1 may be implemented within a single device, or a single device shown in FIG. 1 may be implemented as multiple, distributed devices. Additionally, or alternatively, a set of devices (e.g., one or more devices) of the example environment 100 may perform one or more functions described as being performed by another set of devices of the example environment 100.

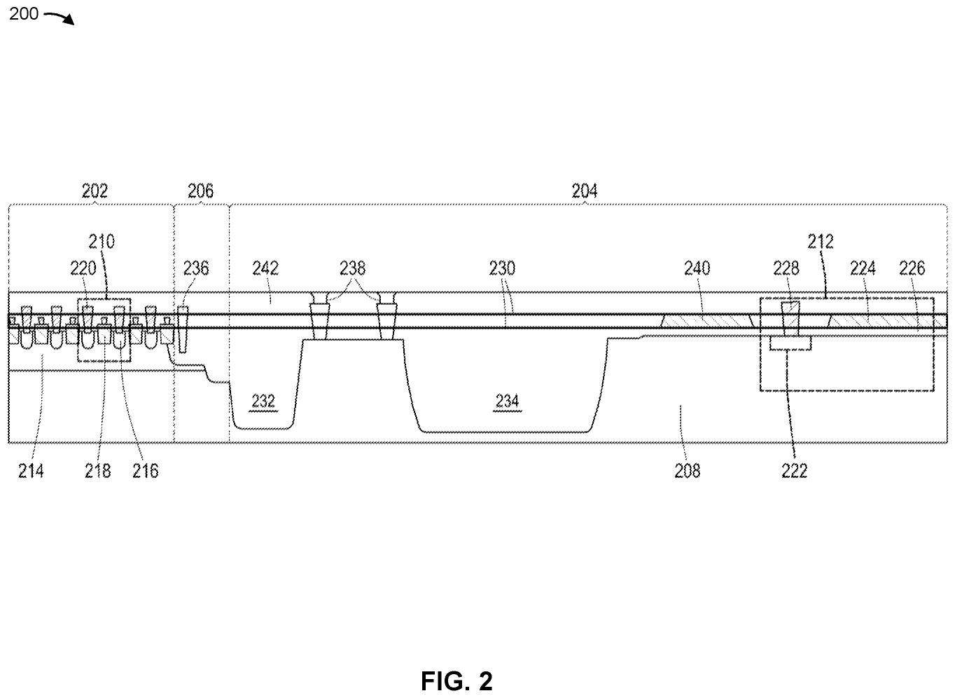

FIG. 2 is a diagram of an example semiconductor device 200 described herein. The semiconductor device 200 may include a logic device (e.g., a processor, a central processing unit (CPU), a graphics processing unit (GPU)), a memory device (e.g., a dynamic random access memory (DRAM) device, a static random access memory (SRAM) device), a display panel device (e.g., a display panel driver including a driver integrated circuit (IC), a line driver IC, a level shifter IC), and/or another type of semiconductor device 200 that includes a high voltage transistor structure.

As shown in FIG. 2, the semiconductor device 200 may include a low voltage device region 202, a high voltage device region 204, and an isolation region 206 between the low voltage device region 202 and the high voltage device region 204. Alternatively, the low voltage device region 202 and the isolation region 206 may be omitted, and the semiconductor device 200 may include only the high voltage device region 204. The low voltage device region 202, the high voltage device region 204, and the isolation region 206 may be formed in and/or on a substrate 208 of the semiconductor device 200.

The low voltage device region 202 may include one or more low voltage transistor structures 210 formed in and/or on the substrate 208. A low voltage transistor structure 210 may refer to a transistor structure that operates based on a relative low voltage, such as approximately 6 volts or less, among other examples. The high voltage device region 204 may include one or more high voltage transistor structures 212. A high voltage transistor structure 212 may refer to a transistor structure that operates based on a relatively high voltage (e.g., relative to the low voltage transistor structure(s) 210), such as approximately 8 volts or greater, among other examples.

The low voltage transistor structure(s) 210 may include one or more low voltage planar transistor structures, one or more low voltage fin field effect transistor (finFET) structures, one or more low voltage nanostructure transistors, and/or one or more low voltage transistor structures of another type. A low voltage finFET transistor structure may include a semiconductor fin structure 214, a plurality of source/drain regions 216 on the semiconductor fin structure 214, and a gate structure 218 that wraps around at least three sides of a portion of the semiconductor fin structure 214 between the source/drain regions 216. The source/drain regions 216 may be physically coupled and/or electrically coupled with one or more contact structures 220, which may also be referred to as source/drain contacts or MDs. A low voltage nanostructure transistor may generally refer to a low voltage transistor structure 210 that includes a nanostructure channel (such as a nanosheet channel, a nanoribbon channel, a nanotube channel, and/or multi-bridge channel, among other examples). The gate structure 218 may fully wrap around the nanostructure channel (e.g., on four sides, on all sides), and the source/drain regions 216 may be included on opposing sides of the nanostructure channel and on opposing sides of the gate structure 218. In some implementations, a low voltage nanostructure transistor may be referred to as a gate all around (GAA) transistor structure or GAA field effect transistor (GAAFET or GAA FET) structure, a low voltage nanowire transistor structure, a low voltage nanosheet transistor structure, a low voltage multi-bridge channel transistor structure, a nanoribbon transistor structure, and/or another type of low voltage nanostructure transistor structure.

A high voltage transistor structure 212 may include a plurality of source/drain regions 222 a gate structure 224 between the source/drain regions 222, and a gate oxide layer 226 between the source/drain regions and between the gate structure 224 and the substrate 208. The source/drain regions 222 may be physically coupled and/or electrically coupled with one or more contact structures 228 (source/drain contacts or MDs). A high voltage transistor structure 212 may include a high voltage planar transistor structure, a high voltage finFET structure, a high voltage nanostructure transistor, and/or another type of high voltage transistor structure.

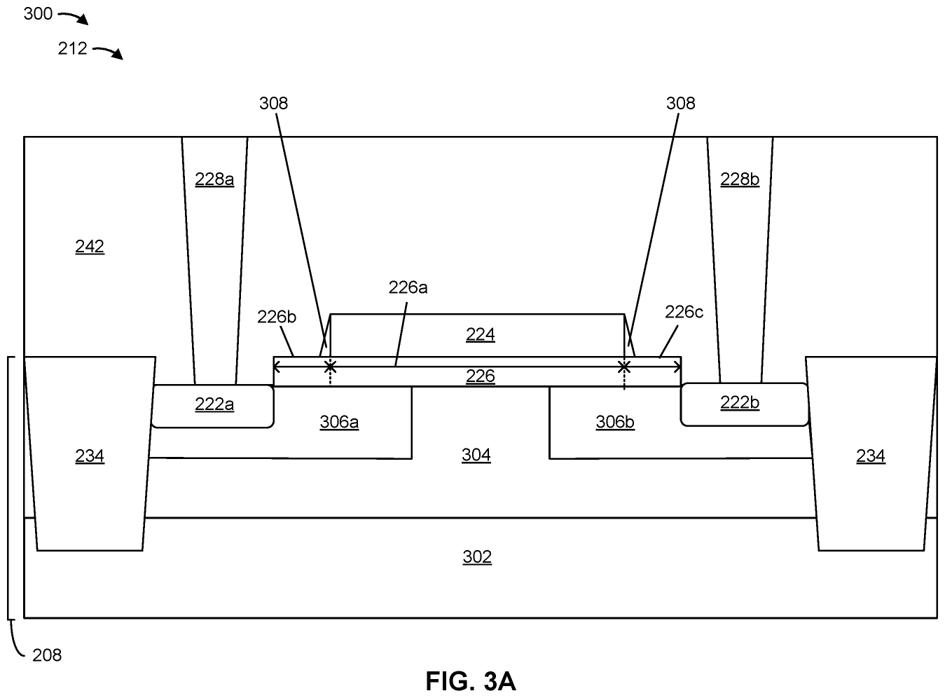

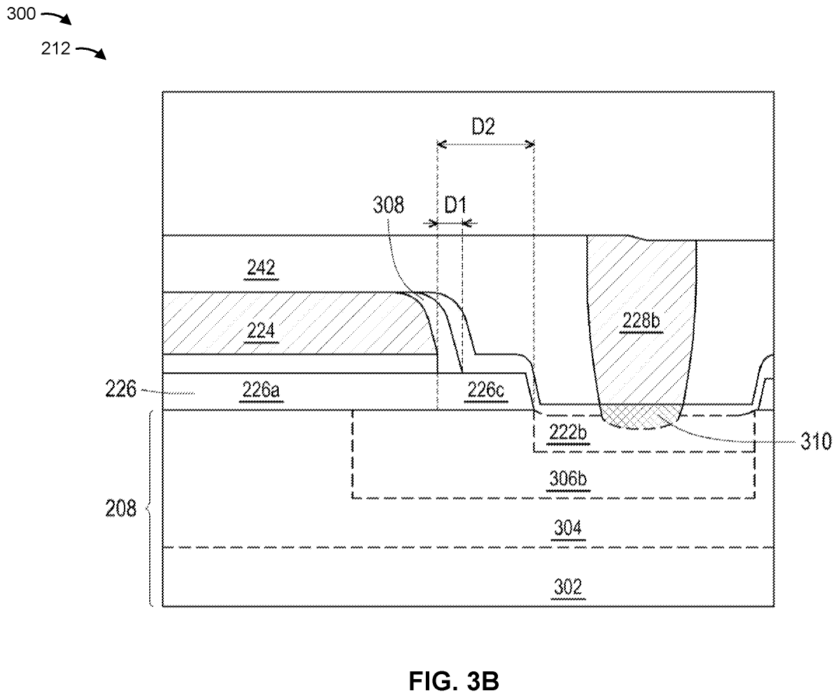

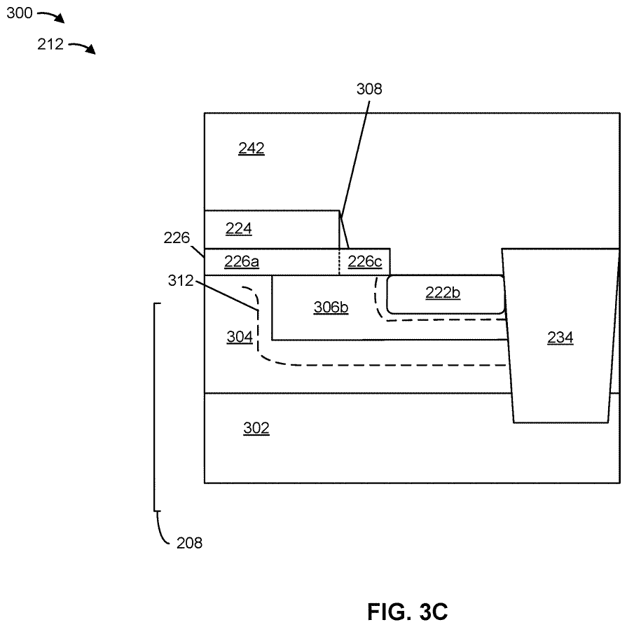

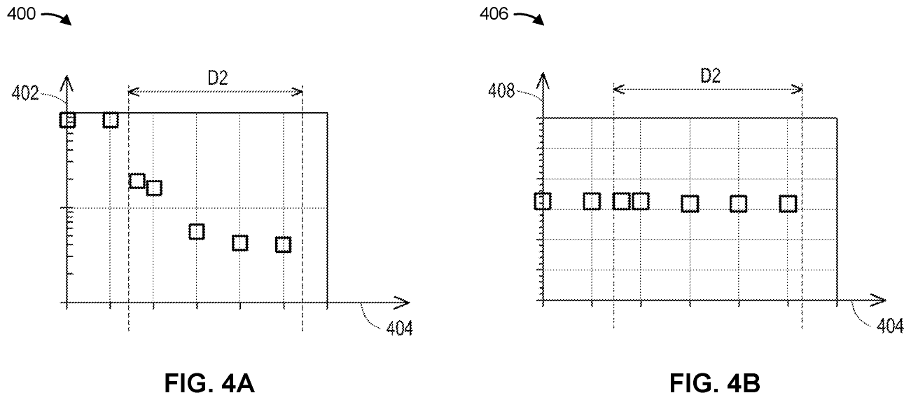

As described herein, such as in connection with FIGS. 3A-3C, 4A, and/or 4B, among other examples, the gate oxide layer 226 may include a first portion that is located under the gate structure 224 and between the gate structure 224 and the substrate 208, and a second portion that extends laterally outward past the gate structure 224 and toward one or more of the source/drain regions 222. The lateral extension of the gate oxide layer 226 outward past the gate structure 224 enables the second portion of the gate oxide layer 226 to be used as a self-aligned implantation mask when forming the source/drain regions 222. This not only reduces the quantity of additional masking layers used for forming source/drain regions 222 (e.g., because the gate oxide layer 226 serves as a masking layer, meaning that the process for forming the source/drain regions 222 is self-aligned), but also enables one or more tuning parameters for the high voltage transistor structure 212 to be optimized, thereby enabling GIDL and/or another performance parameter of the high voltage transistor structure 212 to be improved.

As further shown in FIG. 2, the use of the gate oxide layer 226 as a self-aligned implantation mask integrates into the semiconductor device 200 with advanced semiconductor structures such as finFET structures (e.g., the low voltage transistor structure(s) 210). For example, an alignment overlay 230 shown in FIG. 2 illustrates that a portion of a gate structure 218 (e.g., a low voltage gate structure) on a semiconductor fin structure 214 in the low voltage transistor structure 210, and the gate structure 224 of the high voltage transistor structure 212, are located at approximately a same height in the semiconductor device 200. This enables one or more semiconductor processing operations for the semiconductor device to be performed such that portions of the low voltage transistor structure 210 and portions of the high voltage transistor structure 212 are formed in the same one or more processing operations. For example, the alignment of the gate structures 218 and 224 enables sidewall spacers (or gate spacers) to be formed for the gate structures 218 and 224 in the same set of one or more semiconductor processing operations. In this way, separate spacer formation operations are not needed for forming the sidewall spacers for the gate structures 218 and 224, which reduces semiconductor processing cost, reduces semiconductor processing time, and/or reduces the consumption of semiconductor processing resources (e.g., processing chemicals, semiconductor processing facility power) for forming the semiconductor device 200, among other examples.

As further shown in FIG. 2, one or more isolation regions and/or one or more isolation structures may be included in the between the low voltage device region 202 and the high voltage device region 204 to provide electrical isolation and/or thermal isolation between the low voltage device region 202 and the high voltage device region 204. For example, a low voltage shallow trench isolation (STI) region 232 may be included in the isolation region 206 and/or in the high voltage device region 204, among other examples. As another example, an STI region 234 (e.g., a high voltage STI region) may be included in the high voltage device region 204. As another example, isolation structures 236 and/or 238 may be included in the isolation region 206 and/or in the high voltage device region 204. The isolation structures 236 and/or 238 may include trenches, vias, and/or other types of structures. As another example, a dummy gate structure 240 (e.g., a non-active gate structure) may be included in the high voltage device region 204.

As further shown in FIG. 2, a dielectric region 242 may be included over and/or on the low voltage transistor structure(s) 210 and the high voltage transistor structure(s) 212. The dielectric region 242 may be included to provide additional electrical isolation and/or additional thermal isolation, as well as providing a substantially planar surface on which subsequent layers and/or structures of the semiconductor device 200 may be formed.

As indicated above, FIG. 2 is provided as an example. Other examples may differ from what is described with regard to FIG. 2.

FIGS. 3A-3C are diagrams of an example implementation 300 of a high voltage transistor structure 212 described herein. The high voltage transistor structure 212 may be included in the semiconductor device 200 described herein.

As shown in FIG. 3A, the high voltage transistor structure 212 may be formed in the substrate 208. The substrate 208 may include a silicon (Si) substrate, a substrate formed of a material including silicon, a III-V compound semiconductor material substrate such as gallium arsenide (GaAs), a silicon on insulator (SOI) substrate, a germanium (Ge) substrate, a silicon germanium (SiGe) substrate, a silicon carbide (SiC) substrate, or another type of semiconductor substrate. The substrate 208 may include various layers, including conductive or insulating layers formed on a semiconductor substrate. The substrate 208 may include a compound semiconductor and/or an alloy semiconductor. The substrate 208 may include various doping configurations to satisfy one or more design parameters. For example, different doping profiles (e.g., n-wells, p-wells) may be formed on the substrate 208 in regions designed for different device types (e.g., p-type metal-oxide semiconductor (PMOS) nanostructure transistors, n-type metal-oxide semiconductor (NMOS) nanostructure transistors). The suitable doping may include ion implantation of dopants and/or diffusion processes. Further, the substrate 208 may include an epitaxial layer (epi-layer), may be strained for performance enhancement, and/or may have other suitable enhancement features. The substrate 208 may include a portion of a semiconductor wafer on which other semiconductor devices are formed.

STI regions 234 may be included in the substrate 208 and on opposing sides of the high voltage transistor structure 212. The STI regions 234 may electrically isolate the high voltage transistor structure 212 from other layers, structures, and/or devices in the semiconductor device 200. The STI regions 234 may include a dielectric material such as a silicon oxide (SiOₓ), a silicon nitride (SiₓN_{y}), a silicon oxynitride (SiON), fluoride-doped silicate glass (FSG), a low dielectric constant (low-k) dielectric material, and/or another suitable insulating material. The STI regions 234 may include a multi-layer structure, for example, having one or more liner layers.

As further shown in FIG. 3A, the high voltage transistor structure 212 may include a deep well 302 in the substrate. The deep well 302 may include a deep n-well, a deep p-well, and/or another type of deep well. A deep n-well may refer to a region of the substrate 208 that includes a semiconductor material (e.g., silicon (Si) and/or another semiconductor material) that is doped with one or more n-type dopants. Examples of n-type dopants include phosphorous (P), arsenic (As), and/or stibium (Sb), among other examples. A deep p-well may refer to a region of the substrate 208 that includes a semiconductor material (e.g., silicon (Si) and/or another semiconductor material) that is doped with one or more p-type dopants. Examples of p-type dopants include boron (B), gallium (Ga), and/or indium (In), among other examples.

As further shown in FIG. 3A, the high voltage transistor structure 212 may include a p-well region 304 over and/or on the deep well 302. The p-well region 304 may include a region of the substrate 208 that includes a semiconductor material (e.g., silicon (Si) and/or another semiconductor material) that is doped with one or more p-type dopants (e.g., boron (B), gallium (Ga), and/or indium (In), among other examples).

As further shown in FIG. 3A, the high voltage transistor structure 212 may include a plurality of n-type lightly-doped source/drain (NLDD) regions in the p-well region 304. The NLDD regions may include an NLDD region 306a and an NLDD region 306b that are electrically separated and/or physically separated by the p-well region 304. The NLDD regions 306a and 306b may include regions of the substrate 208 that includes a semiconductor material (e.g., silicon (Si) and/or another semiconductor material) that is lightly doped with one or more n-type dopants (e.g., phosphorous (P), arsenic (As), and/or stibium (Sb), among other examples). For example, the NLDD regions 306a and 306b may be “lightly doped” in that the NLDD regions 306a and 306b may include a concentration of dopants that is included in a range of approximately 1E¹¹ n-type ions per cm² to approximately 5E¹³ n-type ions per cm². However, other values for the range are within the scope of the present disclosure. The light doping in the NLDD regions 306a and 306b enables a threshold voltage (Vₜ) of the high voltage transistor structure 212 to be reduced while enabling medium to high voltage operation at one or more source/drain regions 222a and/or 222b of the high voltage transistor structure 212.

The high voltage transistor structure 212 may include a source/drain region 222a and a source/drain region 222b. The source/drain regions 222a and 222b may each include silicon (Si) with one or more dopants, such as a p-type material (e.g., boron (B) or germanium (Ge), among other examples), an n-type material (e.g., phosphorous (P) or arsenic (As), among other examples), and/or another type of dopant. The source/drain region 222a may be included in the NLDD region 306a in the substrate 208. The source/drain region 222b may be included in the NLDD region 306b in the substrate 208.

The concentration of dopants in the source/drain regions 222a and 222b may be greater relative to the concentration of dopants in the NLDD regions 306a and 306b. For example, the NLDD regions 306a and/or 306b may be “lightly-doped” in that the NLDD region 306a and/or 306b may include a concentration of dopants that is included in a range of approximately 1E¹¹ n-type ions per cm² to approximately 5E¹³ n-type ions per cm², whereas the source/drain regions 222a and/or 222b may each include a concentration of dopants that is included in a range of approximately 1E¹⁴ n-type ions per cm² to approximately 1E¹⁶ n-type ions per cm². However, other values for these ranges are within the scope of the present disclosure.

The NLDD regions 306a and/or 306b may include a concentration of dopants that is included in a range of approximately 1E¹¹ n-type ions per cm² to approximately 5E¹³ n-type ions per cm² to achieve a sufficiently high on-mode current for the high voltage semiconductor device 212, and/or to achieve a sufficiently low off-mode current leakage for the high voltage semiconductor device 212. However, other values for the range are within the scope of the present disclosure.

The high voltage transistor structure 212 may include a gate structure 224 between the source/drain regions 222a and 222b. The gate structure 224 may be formed of one or more layers and/or one or more materials. The gate structure 224 may include one or more metal materials, one or more high dielectric constant (high-k) materials, and/or one or more other types of materials. For example, the gate structure 224 may include a work function tuning layer, an interfacial layer, and/or a metal electrode layer, among other examples.

The high voltage transistor structure 212 may include a gate oxide layer 226. In some implementations, the gate oxide layer 226 is included on the substrate 208. In some implementations, the gate oxide layer 226 is recessed in the substrate 208 such that a top surface of the gate oxide layer 226 is at approximately a same height as a top surfaces of the STI regions 234. The gate oxide layer 226 may be included between the source/drain region 222a and 222b. In some implementations, the height of the top surfaces of the source/drain region 222a and 222b is at approximately the same height as the top surface of the gate oxide layer 226. In some implementations, the height of the top surfaces of the source/drain region 222a and 222b is lower than the height of the top surface of the gate oxide layer 226. In some implementations, the height of the top surfaces of the source/drain region 222a and 222b is at approximately the same height as the top surfaces of the STI regions 234. In some implementations, the height of the top surfaces of the source/drain region 222a and 222b is lower than the height of the top surfaces of the STI regions 234.

The gate oxide layer 226 may include an oxide material (e.g., an HTO and/or another type of gate oxide) and/or another type of dielectric material. The gate oxide layer 226 may have a sufficient thickness to support the high voltages (e.g., 6 volts, 8 volts, and/or greater voltages) handled by the high voltage transistor structure 212. For example, the thickness of the gate oxide layer 226 may be included in a range of approximately 150 angstroms to approximately 300 angstroms to support the medium to high voltages handled by the high voltage transistor structure 212. However, other values for the range are within the scope of the present disclosure.

The high voltage transistor structure 212 includes a portion 226a of the gate oxide layer 226 under the gate structure 224. The portion 226a may be located between the gate structure 224 and the substrate 208, and may be located within a perimeter of the gate structure 224. The portion 226a may be included at least partially on a portion of the p-well region 304, at least partially on a portion of the NLDD region 306a, and/or at least partially on a portion of the NLDD region 306b, among other examples. The high voltage transistor structure 212 further includes portions 226b and/or 226c of the gate oxide layer 226 that are not located under the gate structure 224 and are instead located outside of a perimeter of the gate structure 224. The inclusion of the portions 226b and/or 226c of the gate oxide layer 226 results in the gate oxide layer 226 extending laterally outward from the gate structure 224 (e.g., laterally outward from under the gate structure 224) such that the portions 226b and/or 226c of the gate oxide layer 226 are not under the gate structure 224. The portion 226b may extend between the gate structure 224 and the source/drain region 222a and may be located at least partially over and/or on a portion of the NLDD region 306a. The portion 226c may extend between the gate structure 224 and the source/drain region 222b and may be located at least partially over and/or on a portion of the NLDD region 306b.

The gate oxide layer 226 may be formed such that the portions 226b and/or 226c of the gate oxide layer 226 (e.g., the portions that extend laterally outward from the gate structure 224) can be used to tune the placement or location of the source/drain regions 222a and/or 222b to prevent or reduce the likelihood of GIDL in the high voltage transistor structure 212. In particular, the gate oxide layer 226 may be formed such that the portions 226b and/or 226c of the gate oxide layer 226 can be used to tune the spacing or distance between the gate structure 224 and the source/drain regions 222a and/or 222b. Tuning the spacing or distance between the gate structure 224 and the source/drain regions 222a and/or 222b enables a particular profile for a depletion region in the high voltage semiconductor device 212 to be achieved such that GIDL in the high voltage transistor structure 212 is prevented (or the likelihood of GIDL is reduced). An example profile for the depletion region is illustrated and described in connection with FIG. 3C.

As further shown in FIG. 3A, one or more sidewall spacers 308 may be included over and/or on sidewalls of the gate structure 224. The one or more sidewall spacers 308 may include one or more low dielectric constant (low-k) materials having a dielectric constant that is less than the dielectric constant of silicon oxide (e.g., less than approximately 3.9), a silicon oxide (SiOₓ), a silicon oxynitride (SiON), a silicon nitride (SiₓN_{y}), silicon oxycarbonitride (SiOCN), and/or another suitable dielectric material.

The high voltage transistor structure 212 may include a first sidewall spacer 308 on a first sidewall of the gate structure 224 facing source/drain region 222a, and a second sidewall spacer 308 on a second sidewall of the gate structure 224 facing the source/drain region 222b. The portion 226b of the gate oxide layer 226 may extend laterally outward past the first sidewall spacer 308, and the portion 226c of the gate oxide layer 226 may extend laterally outward past the second sidewall spacer 308. The sidewall spacer(s) 308 may include a sloped and/or rounded outer sidewall that results from one or more semiconductor processing operations that are performed subsequent to the formation of the sidewall spacers 308.

In some implementations, a sidewall spacer 308 includes a single-layer sidewall spacer that is formed during a single sidewall spacer formation process. In some implementations, a sidewall spacer 308 includes a multiple-layer structure. In some implementations, a single set of one or more sidewall spacer formation operations is performed to form the sidewall spacer(s) 308 of the high voltage transistor structure 212 and the sidewall spacer(s) of a low voltage transistor structure 210 included in the semiconductor device 200. In this way, the formation of the sidewall spacer(s) 308 of the high voltage transistor structure 212 and the formation of the sidewall spacer(s) of the low voltage transistor structure 210 are integrated into the same process, which reduces semiconductor processing cost, reduces semiconductor processing time, and/or reduces the consumption of semiconductor processing resources (e.g., processing chemicals, semiconductor processing facility power) for forming the semiconductor device 200, among other examples.

A contact structure 228a (e.g., a source/drain contact or MD) may be included over and/or on the source/drain region 222a. A contact structure 228b (e.g., a source/drain contact or MD) may be included over and/or on the source/drain region 222b. The contact structures 228a and 228b may each include a via, an interconnect, a trench, a contact plug, and/or another type of electrically conductive structure. The contact structures 228a and 228b may each include tungsten (W), cobalt (Co), ruthenium (Ru), titanium (Ti), aluminum (Al), copper (Cu) or gold (Au), among other examples of electrically conductive materials.

The contact structures 228a and 228b may be included in the dielectric region 242 of the semiconductor device 200. The dielectric region 242 may include an interlayer dielectric (ILD) layer or another type of dielectric region. The dielectric region 242 may be included over the source/drain regions 222a and 222b, over and/or on the gate structure 224, and/or over and/or on the portions 226b and/or 226c of the gate oxide layer 226, among other examples. The dielectric region 242 may be included to provide electrical isolation and/or insulation between the gate structure 224 and/or the source/drain regions 222a and 222b of the high voltage transistor structure 212, among other examples. The dielectric region 242 may include a silicon nitride (SiNₓ), an oxide (e.g., a silicon oxide (SiOₓ) and/or another oxide material), and/or another type of dielectric material.

The dopant types of the various regions and/or layers illustrated and described in connection with FIG. 3A are examples, and the high voltage transistor structure 212 may include another configuration of dopant types for the various regions and/or layers. For example, the p-well region 304 may alternatively include an n-well region, the NLDD regions 306a and 306b may alternatively include p-well lightly-doped (PLDD) regions, and/or the source/drain regions 222a and 222b may include p-type doped source/drain regions.

In general, the high voltage transistor structure 212 may include a first doped region (e.g., the p-well region 304), that includes a first dopant type, in the substrate 208 of the semiconductor device 200. The high voltage transistor structure 212 may include a second doped region (e.g., the NLDD region 306b), that includes a second dopant type, in the substrate 208 and adjacent to the first doped region. The high voltage transistor structure 212 may include a first source/drain region 222a that includes the second dopant type in the substrate 208. The high voltage transistor structure 212 may include a second source/drain region 222b that includes the second dopant type in the substrate 208 and on and/or adjacent to the second doped region. The high voltage transistor structure 212 may include a gate structure 224 between the first source/drain region 222a and the second source/drain region 222b. The high voltage transistor structure 212 may include a gate oxide layer 226 between the first source/drain region 222a and the second source/drain region 222b, where a first portion 226a of the gate oxide layer 226 is under the gate structure 224 and between the gate structure 224 and the substrate 208, and at least a second portion (e.g., the portion 226b, the portion 226b) of the gate oxide layer extends laterally outward past the gate structure 224 from the first portion 226a.

FIG. 3B illustrates a close-up view of a portion of the high voltage transistor structure 212. As shown in FIG. 3B, in some implementations, one or more silicide layers 310 (e.g., a metal silicide layer such as a titanium silicide layer) are included on the source/drain region 222b to reduce contact resistance for the source/drain region 222b. In some implementations, one or more silicide layers 310 are also included on the source/drain region 222a to reduce contact resistance for the source/drain region 222a.

FIG. 3B further illustrates one or more dimensions of the high voltage transistor structure 212. As shown in FIG. 3B, the high voltage transistor structure 212 may include an example dimension D1. The example dimension D1 may correspond to a thickness of a sidewall spacer 308 on a sidewall of the gate structure 224 of the high voltage transistor structure 212. In some implementations, the example dimension D1 is included in a range of approximately 8 nanometers to approximately 10 nanometers. However, other values for the range are within the scope of the present disclosure. In some implementations, the thickness of the sidewall spacer 308 (e.g., the example dimension D1) and a thickness of a sidewall spacer of a low voltage transistor structure 210 included in the semiconductor device 200 may be approximately a same thickness. The approximate same thickness of the sidewall spacer 308 and the sidewall spacer of the low voltage transistor structure 210 included in the semiconductor device 200 may result from the process integration of forming the sidewall spacer 308 and the sidewall spacer of the low voltage transistor structure 210 in the same set of one or more semiconductor processing operations.

As further shown in FIG. 3B, the high voltage transistor structure 212 may include another example dimension D2. The example dimension D2 may correspond to a width of an portion 226c (or a portion 226b) of the gate oxide layer 226 that extends laterally outward from the gate structure 224 of the high voltage transistor structure 212. The example dimension D2 may also correspond to a distance between a sidewall of the gate structure 224 and the source/drain region 222b (or the source/drain region 222a). The example dimension D2 (e.g., the width of the portion 226b and/or the 226c) may be greater relative to the example dimension D1 (e.g., the thickness of the sidewall spacers 308) such that the portion 226b and/or the 226c extend laterally outward from the sidewall spacers 308. In some implementations, the example dimension D2 is included in a range of approximately 0.014 microns to approximately 0.05 microns. If the example dimension D2 is less than approximately 0.014 microns, the high voltage transistor structure 212 may experience a relatively high GIDL. If the example dimension D2 is greater than approximately 0.05 microns, the driver current for the high voltage transistor structure 212 may be too low for the high voltage operation of the high voltage transistor structure 212. If the example dimension D2 is included in the range of approximately 0.014 microns to approximately 0.05 microns, a relatively high device density may be achieved for the semiconductor device 200 while achieving a sufficiently high drive current and a sufficiently low GIDL for the high voltage transistor structure 212. However, other values for the range are within the scope of the present disclosure.

In some implementations, the example dimension D2 may be selected based on one or more parameters or attributes associated with the high voltage transistor structure 212. For example, the example dimension D2 may be selected to tune the spacing or distance between the gate structure 224 and the source/drain region 222b and/or the source/drain region 222a based on parameters and/or attributes of the high voltage transistor structure 212, such as the thickness of the gate oxide layer 226, the thickness of the sidewall spacer 308 (e.g., the example dimension D1), the gate length, the drain voltage for the high voltage transistor structure 212, the gate voltage for the high voltage transistor structure 212, and/or another parameter or attribute of the high voltage transistor structure 212. As an example, the example dimension D2 may be increased for greater drain voltages and/or greater gate voltages. As an example, the example dimension D2 may be decreased for lesser drain voltages and/or lesser gate voltages. The example dimension D2 may be selected to tune the spacing or distance between the gate structure 224 and the source/drain region 222b and/or the source/drain region 222a to achieve a relatively low GIDL (e.g., a GIDL that satisfies a threshold) based on these parameters and/or attributes of the high voltage transistor structure 212.

FIG. 3C illustrates an example profile for a depletion region 312 for the high voltage transistor structure 212. The example profile for the depletion region 312 occurs as a result of the spacing between the gate structure 224 and the source/drain region 222b provided by the gate oxide layer 226. As shown in FIG. 3C, the depletion region 312 occurs in the p-well region 304 and in the NLDD region 306b. The depletion region 312 bends around the source/drain region 222b and does not encroach into the source/drain region 222b because of the spacing between the gate structure 224 and the source/drain region 222b provided by the gate oxide layer 226. If the gate oxide layer 226 extends laterally outward from the gate structure 224 toward the source/drain region 222a, the depletion region 312 may conform to a similar profile around the source/drain region 222a.

As indicated above, FIGS. 3A-3C are provided as an example. Other examples may differ from what is described with regard to FIGS. 3A-3C.

FIGS. 4A and 4B are diagrams of example tuning parameters for a high voltage transistor structure 212 described herein. FIG. 4A illustrates an example tuning parameter 400 corresponding to GIDL 402 of the high voltage transistor structure 212 as a function of a distance 404 (or spacing) between the gate structure 224 and a source/drain region 222a and/or a source/drain region 222b of the high voltage transistor structure 212 (corresponding to the example dimension D2). FIG. 4B illustrates an example tuning parameter 406 corresponding to drain saturation current 408 of the high voltage transistor structure 212 as a function of the distance 404 (or spacing) between the gate structure 224 and a source/drain region 222a and/or a source/drain region 222b of the high voltage transistor structure 212.

The portions 226b and/or 226c of the gate oxide layer 226 may enable the distance 404 (or spacing) between the gate structure 224 and the source/drain region 222a and/or the source/drain region 222b of the high voltage transistor structure 212 to be within the range described above for the example dimension D2. As shown in FIGS. 4A and 4B forming the gate structure 224 and the source/drain region 222a and/or the source/drain region 222b such that the distance 404 is within the range described above for the example dimension D2 may achieve a relatively low GIDL 402 for the high voltage transistor structure 212 with minimal to no impact on drain saturation current 408 for the high voltage transistor structure 212.

As indicated above, FIGS. 4A and 4B are provided as an example. Other examples may differ from what is described with regard to FIGS. 4A and 4B.

FIGS. 5A-5M are diagrams of an example implementation 500 described herein. The example implementation 500 includes an example of forming a high voltage transistor structure 212 of the semiconductor device 200 described herein.

As shown in FIG. 5A, the example implementation 500 of forming the high voltage transistor structure 212 may include a plurality of semiconductor processing operations. For example, an STI formation operation 502 may be performed to form STI regions 234 in the substrate 208 of the semiconductor device. As another example, a well implantation operation 504 may be performed to form the deep well 302 and the p-well region 304 in the substrate 208. As another example, a lightly-doped implantation operation 506 may be performed to form the NLDD regions 306a and 306b in the substrate 208. As another example, an oxide formation operation 508 may be performed to form an oxide layer over and/or on the substrate 208. As another example, a gate formation operation 510 may be performed to form the gate structure 224 of the high voltage transistor structure 212. As another example, a spacer formation operation 512 may be performed to form the sidewall spacers 308 on the sidewalls of the gate structure 224. As another example, a gate oxide etch operation 514 (also referred to as a source/drain open operation) may be performed to etch the oxide layer to form the gate oxide layer 226 of the high voltage transistor structure 212. As another example, a source/drain implantation operation 516 may be performed to form the source/drain regions 222a and 222b of the high voltage transistor structure 212 using the gate oxide layer 226 as a self-aligned implantation mask. As another example, an ILD formation operation 518 may be performed to form the dielectric region 242 of the semiconductor device 200. As another example, an MD formation operation 520 may be performed to form the contact structures 228a and 228b.

In some implementations, one or more of the semiconductor processing operations 502-520 described in connection with the example implementation 500 may be performed by one or more of the semiconductor processing tools 102-114 and/or by the wafer/die transport tool 116. In some implementations, one or more of the semiconductor processing operations 502-520 described in connection with the example implementation 500 may be performed by another semiconductor processing tool. In some implementations, one or more of the semiconductor processing operations 502-520 may be performed to form one or more low voltage transistor structures 210 (e.g., one or more low voltage finFET structures) of the semiconductor device 200 such that processing of the high voltage transistor structure 212 and processing of the one or more low voltage transistor structures 210 are integrated into the same set of processing operations. For example, a single sidewall spacer formation process (e.g., a single spacer formation operation 512) may be performed to form the sidewall spacers 308 on the sidewalls of the gate structure 224 of the high voltage transistor structure 212 and to form sidewall spacers on gate structure(s) of the one or more low voltage transistor structure 210.

Turning to FIG. 5B, the substrate 208 may be provided. The substrate 208 may be provided as a semiconductor wafer, a semiconductor die, and/or another type of semiconductor substrate. In some implementations, the substrate 208 may be a doped substrate, such as a semiconductor substrate that is doped with one or more p-type dopants, a semiconductor substrate that is doped with one or more n-type dopants, and/or another type of doped substrate. In some implementations, the substrate 208 has a bulk resistivity (or volumetric resistivity) that is included in a range of approximately 1 ohm-centimeter to approximately 100 ohm-centimeters. However, other values for the range are within the scope of the present disclosure.

As shown in FIG. 5C, the STI formation operation 502 may be performed to form STI regions 234 in the substrate 208. To form the STI regions 234, recesses may be formed in the substrate 208, and the material of the STI regions 234 may be deposited in the recesses.

In some implementations, a pattern in a photoresist layer is used to etch the substrate 208 to form the recesses. In these implementations, the deposition tool 102 forms the photoresist layer on the substrate 208. The exposure tool 104 exposes the photoresist layer to a radiation source to pattern the photoresist layer. The developer tool 106 develops and removes portions of the photoresist layer to expose the pattern. The etch tool 108 etches the substrate 208 based on the pattern to form the recesses in the substrate 208. In some implementations, the etch operation includes a plasma etch operation, a wet chemical etch operation, and/or another type of etch operation. In some implementations, a photoresist removal tool removes the remaining portions of the photoresist layer (e.g., using a chemical stripper, plasma ashing, and/or another technique). In some implementations, a hard mask layer is used as an alternative technique for etching the substrate 208 based on a pattern.

The deposition tool 102 may deposit the material of the STI regions 234 in a PVD operation, an ALD operation, a CVD operation, an epitaxy operation, an oxidation operation, another type of deposition operation described in connection with FIG. 1, and/or another suitable deposition operation. In some implementations, the planarization tool 110 planarizes the STI regions 234 after the deposition tool 102 deposits the STI regions 234.

As shown in FIG. 5D, the well implantation operation 504 may be performed to form the deep well 302 and the p-well region 304 in the substrate 208. For example, the deep well 302 may be formed in and/or on the substrate 208. As another example, the p-well region 304 may be formed in the substrate 208 and/or on the deep well 302.

In some implementations, the ion implantation tool 114 forms the deep well 302 by performing an ion implantation operation to implant ions (e.g., p-type ions, n-type ions) into the substrate 208 to form the deep well 302. The ion implantation tool 114 may direct an ion beam toward the substrate 208 such that the ions are implanted below the surface of the substrate 208 to dope the substrate 208. Additionally and/or alternatively, the deposition tool 102 may deposit the deep well 302 in a PVD operation, an ALD operation, a CVD operation, an epitaxy operation, an oxidation operation, another type of deposition operation described in connection with FIG. 1, and/or another suitable deposition operation. In some implementations, the planarization tool 110 planarizes the deep well 302 after the deposition tool 102 deposits the deep well 302.

In some implementations, the ion implantation tool 114 forms the p-well region 304 by performing an ion implantation operation to implant ions (e.g., p-type ions, n-type ions) into the substrate 208 to form the p-well region 304. The ion implantation tool 114 may direct an ion beam toward the substrate 208 such that the ions are implanted below the surface of the substrate 208 to dope the substrate 208. Additionally and/or alternatively, the deposition tool 102 may deposit the p-well region 304 in a PVD operation, an ALD operation, a CVD operation, an epitaxy operation, an oxidation operation, another type of deposition operation described in connection with FIG. 1, and/or another suitable deposition operation. In some implementations, the planarization tool 110 planarizes the p-well region 304 after the deposition tool 102 deposits the p-well region 304. In some implementations, the p-well region 304 may be formed such that the concentration of dopants in the p-well region 304 may be included in a range of approximately 1E¹¹ p-type ions per cm² to approximately 5E¹³ p-type ions per cm². However, other values for the range are within the scope of the present disclosure.

As shown in FIG. 5E, the lightly-doped implantation operation 506 may be performed to form the NLDD regions 306a and 306b in the substrate 208. The NLDD region 306a may be formed in and/or on a portion of the p-well region 304. The NLDD region 306b may be formed in and/or on another portion of the p-well region 304. In some implementations, an implantation mask is used to mask off other portions of the p-well region 304 so that the NLDD region 306a and the NLDD region 306b are formed only in the portions of the p-well region 304. In some implementations, the ion implantation tool 114 forms the NLDD region 306a and the NLDD region 306b by performing an ion implantation operation to implant ions (e.g., p-type ions, n-type ions) into the substrate 208 to form the NLDD region 306a and the NLDD region 306b in the p-well region 304. The ion implantation tool 114 may direct an ion beam toward the p-well region 304 such that the ions are implanted in the p-well region 304 to form the NLDD region 306a and the NLDD region 306b. The NLDD region 306a and the NLDD region 306b may be formed to include a concentration of dopants that is included in a range of approximately 1E¹¹ n-type ions per cm² to approximately 5E¹³ n-type ions per cm² to achieve a sufficiently high on-mode current for the high voltage transistor structure 212, and/or to achieve a sufficiently low off-mode current leakage for the high voltage transistor structure, among other examples. However, other values for the range are within the scope of the present disclosure.

As shown in FIG. 5F, the oxide formation operation 508 may be performed to form an oxide layer 522 over and/or on the substrate 208. In some implementations, the oxide layer 522 may be formed over and/or on the top surface of the p-well region 304, and over and/or on the top surfaces of the NLDD regions 306a and 306b. In some implementations, the oxide formation operation 508 may include a high-temperature thermal oxidation operation to oxidize portions of the NLDD regions 306a and 306b and the p-well region 304 to form the oxide layer 522 in the substrate 208 (e.g., the portions of the substrate 208 corresponding to the portions of the NLDD regions 306a and 306b and the p-well region 304). In these implementations, the oxide layer 522 may be recessed in the substrate 208 such that the top surface of the oxide layer 522 is at approximately a same height as the top surfaces of the STI regions 234. Alternatively, the NLDD regions 306a and 306b and the p-well region 304 may be removed by etching to form a recess in which the oxide layer 522 is deposited and recessed in the substrate 208.

The deposition tool 102 may deposit the oxide layer 522 in a PVD operation, an ALD operation, a CVD operation, a spin-coating operation, an epitaxy operation, an oxidation operation (e.g., a high-temperature thermal oxidation operation), another type of deposition operation described in connection with FIG. 1, and/or another suitable deposition operation. In some implementations, the planarization tool 110 planarizes the oxide layer 522 after the deposition tool 102 deposits the oxide layer 522.

As shown in FIG. 5G, the gate formation operation 510 may be performed to form the gate structure 224 over and/or on the oxide layer 522. The deposition tool 102 and/or the plating tool 112 may deposit the gate structure 224 in a CVD operation, a PVD operation, an ALD operation, an electroplating operation, another deposition operation described above in connection with FIG. 1, and/or another suitable deposition operation. In some implementations, a seed layer is first deposited, and the gate structure 224 is deposited on the seed layer.

As shown in FIG. 5H, the spacer formation operation 512 may be performed to form the sidewall spacers 308 on the sidewalls of the gate structure 224. The deposition tool 102 may deposit the sidewall spacers 308 in a PVD operation, an ALD operation, a CVD operation, an epitaxy operation, an oxidation operation, another type of deposition operation described in connection with FIG. 1, and/or another suitable deposition operation. In some implementations, the deposition tool 102 conformally deposits the material of the sidewall spacers 308 on the sidewalls and top surface of the gate structure 224 and on the top surface of the oxide layer 522. The etch tool 108 may subsequently perform an etch back operation to remove the material of the sidewall spacers 308 from the top surface of the oxide layer 522 and from the top surface of the gate structure 224. Accordingly, the sidewall spacers 308 may remain on the sidewalls of the gate structure 224.

As shown in FIG. 5I, the gate oxide etch operation 514 may be performed to remove portions of the oxide layer 522 to form the gate oxide layer 226 from the oxide layer 522. The etch tool 108 may perform an etch operation to remove the portions of the oxide layer 522 such portions 226b and/or 226c of the gate oxide layer 226 extend laterally outward from under the gate structure 224 (and laterally outward from the sidewall spacers 308), whereas a portion 226a of the gate oxide layer 226 is included under the gate structure 224. In some implementations, the etch operation includes a plasma etch operation, a wet chemical etch operation, and/or another type of etch operation. The etch operation results in rounding or slanting of the outer sidewalls of the sidewall spacers 308, as shown in the example in FIG. 5I.

As shown in FIG. 5J, the source/drain implant operation 516 may be performed to form the source/drain regions 222a and 222b. The source/drain region 222a may be formed on and/or in the NLDD region 306a. The source/drain region 222a may be formed at a first side of the gate structure 224 between an STI region 234 and the portion 226b of the gate oxide layer 226. The source/drain region 222b may be formed on and/or in the NLDD region 306b. The source/drain region 222b may be formed at a second side of the gate structure 224 between an STI region 234 and the portion 226c of the gate oxide layer 226.

In some implementations, the ion implantation tool 114 forms the source/drain regions 222a and 222b by performing one or more ion implantation operations to implant ions 524 (e.g., p-type ions, n-type ions) into the substrate 208 (e.g., into the NLDD regions 306a and 306b in the substrate 208) to form the source/drain regions 222a and 222b. The ion implantation tool 114 may direct an ion beam toward the substrate 208 such that the ions 524 are implanted below the top surface of the substrate 208 to form the source/drain regions 222a and 222b. Additionally and/or alternatively, etching of the oxide layer 522 may leave behind recesses in the substrate 208 (e.g., in the NLDD regions 306a and/or 306b in the substrate 208) because of the oxide layer 522 being recessed in the substrate 208, and the deposition tool 102 may be used to forming silicon regions in the recesses, which may then be subsequently doped using the ion implantation tool 114 to form the source/drain regions 222a and 222b. Alternatively, no additional epitaxial growth is performed, and the source/drain regions 222a and 222b are formed by doping the NLDD regions 306a and/or 306b in regions that are lower than the oxide layer 522, as shown in the example in FIG. 5J.

The source/drain regions 222a and 222b may each be formed to include a concentration of dopants that is included in a range of approximately 1E¹⁴ n-type ions per cm² to approximately 1E¹⁶ n-type ions per cm² to achieve a sufficiently high on-mode current for the high voltage transistor structure 212, and/or to achieve a sufficiently low off-mode current leakage for the high voltage transistor structure 212. However, other values for these ranges are within the scope of the present disclosure.

The source/drain implant operation 516 may be performed to dope the substrate 208 (or the epitaxially grown silicon regions) to form the source/drain regions 222a and 222b using the gate oxide layer 226 as a self-aligned implantation mask. In particular, the portions 226b and/or 226c of the gate oxide layer 226 that extend laterally outward from the portion 226a of the gate oxide layer 226 and extend laterally outward from under the gate structure 224 may be used as the self-aligned implantation mask to define the location in the substrate 208 (or the epitaxially grown silicon regions) at which the source/drain regions 222a and 222b are implanted.

Implantation of the ions 524 into the substrate 208 is blocked in locations of the substrate 208 covered by the gate oxide layer 226, whereas implantation of the ions 524 into the substrate 208 is permitted in location of the substrate 208 that are exposed (e.g., that are not covered by the gate oxide layer 226).

The gate oxide etch operation 514 described above in connection with FIG. 5I may be performed to achieve a particular distance or threshold distance (e.g., the example dimension D2) between the sidewall(s) of the gate structure 224 and the source/drain region 222a and/or 222b. This enables the source/drain region 222a and/or 222b to be formed in a self-aligned manner in which the distance between the gate structure 224 and the source/drain region 222a and/or 222b is tuned or optimized to reduce, minimize, and/or prevent GIDL in the high voltage transistor structure 212. For example, threshold distance (e.g., the example dimension D2) may be included in a range of approximately 0.014 microns to approximately 0.05 microns, as described above in connection with FIG. 3B. However, other values for the range are within the scope of the present disclosure. In some implementations, the threshold distance may be selected based on and/or to achieve or satisfy a GIDL parameter (or GIDL threshold) for the high voltage transistor structure 212. In some implementations, the threshold distance may be selected based on a gate-to-drain spacing parameter for the high voltage transistor structure 212, a drain voltage of the high voltage transistor structure 212, a gate voltage of the high voltage transistor structure 212, and/or based on another parameter or attribute of the high voltage transistor structure 212.

As shown in FIG. 5K, the ILD formation operation 518 may be performed to form the dielectric region 242. The dielectric region 242 may be formed over and/or on the source/drain regions 222a and/or 222b, over and/or on the gate structure 224, over and/or on the exposed portions 226b and 226c of the gate oxide layer 226, and/or over and/or on the STI regions 234, among other examples. The deposition tool 102 may deposit the dielectric region 242 in one or more PVD operations, one or more ALD operations, one or more CVD operations, one or more epitaxy operations, one or more oxidation operations, one or more of another type of deposition operations described in connection with FIG. 1, and/or one or more other suitable deposition operations. In some implementations, the planarization tool 110 planarizes the dielectric region 242 after the deposition tool 102 deposits the dielectric region 242.

As shown in FIGS. 5L and 5M, an MD formation operation 520 may be performed to form contact structures 228a and 228b respectively over and/or on the source/drain region 222a and 222b. As shown in FIG. 5L, recesses 526 may be formed in and/or through the dielectric region 242 to the top surfaces of the source/drain region 222a and 222b in the MD formation operation 520. The top surfaces of the source/drain region 222a and 222b are exposed through the recesses 526.

In some implementations, a pattern in a photoresist layer is used to etch the dielectric region 242 to form the recesses 526. In these implementations, the deposition tool 102 forms the photoresist layer on the dielectric region 242. The exposure tool 104 exposes the photoresist layer to a radiation source to pattern the photoresist layer. The developer tool 106 develops and removes portions of the photoresist layer to expose the pattern. The etch tool 108 etches the dielectric region 242 based on the pattern to form the recesses 526 in the dielectric region 242. In some implementations, the etch operation includes a plasma etch operation, a wet chemical etch operation, and/or another type of etch operation. In some implementations, a photoresist removal tool removes the remaining portions of the photoresist layer (e.g., using a chemical stripper, plasma ashing, and/or another technique). In some implementations, a hard mask layer is used as an alternative technique for etching the dielectric region 242 based on a pattern.

As shown in FIG. 5M, the contact structures 228a and 228b may be formed in the recesses 526 as part of the MD formation operation 520. The contact structure 228a may be formed such that the contact structure 228a lands on the source/drain region 222a. The contact structure 228b may be formed such that the contact structure 228b lands on the source/drain region 222b. The deposition tool 102 and/or the plating tool 112 may deposit the contact structures 228a and 228b in a CVD operation, a PVD operation, an ALD operation, an electroplating operation, another deposition operation described above in connection with FIG. 1, and/or another suitable deposition operation. In some implementations, a seed layer is first deposited, and the contact structures 228a and/or 228b is deposited on the seed layer. In some implementations, the planarization tool 110 planarizes the contact structures 228a and/or 228b after the deposition tool 102 and/or the plating tool 112 deposits the contact structures 228a and/or 228b.

In some implementations one or more silicide layers 310 (e.g., a metal silicide layer such as a titanium silicide layer) may be formed on the source/drain regions 222a and 222b to reduce contact resistance for the source/drain region 222a and 222b. The silicide layer(s) 310 may be formed on the source/drain regions 222a and 222b through the recesses 526 prior to formation of the contact structures 228a and 228b. Accordingly, the contact structures 228a and 228b may be formed on the silicide layer(s) 310 that are respective formed on the source/drain regions 222a and 222b.

As indicated above, FIGS. 5A-5M are provided as an example. Other examples may differ from what is described with regard to FIGS. 5A-5M.

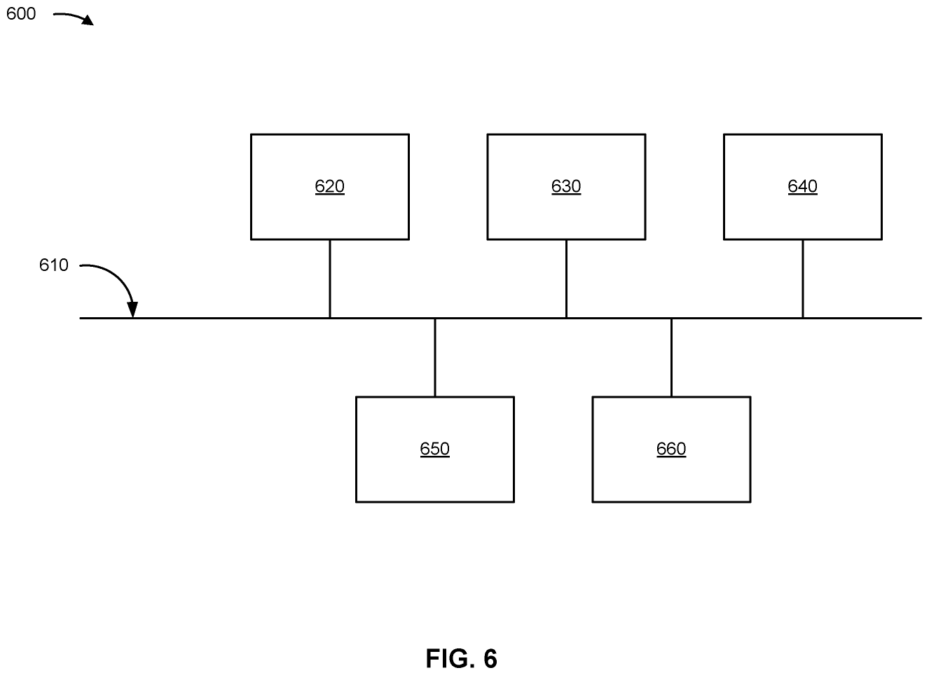

FIG. 6 is a diagram of example components of a device 600 described herein. In some implementations, one or more of the semiconductor processing tools 102-114 and/or the wafer/die transport tool 116 may include one or more devices 600 and/or one or more components of the device 600. As shown in FIG. 6, the device 600 may include a bus 610, a processor 620, a memory 630, an input component 640, an output component 650, and/or a communication component 660.

The bus 610 may include one or more components that enable wired and/or wireless communication among the components of the device 600. The bus 610 may couple together two or more components of FIG. 6, such as via operative coupling, communicative coupling, electronic coupling, and/or electric coupling. For example, the bus 610 may include an electrical connection (e.g., a wire, a trace, and/or a lead) and/or a wireless bus. The processor 620 may include a central processing unit, a graphics processing unit, a microprocessor, a controller, a microcontroller, a digital signal processor, a field-programmable gate array, an application-specific integrated circuit, and/or another type of processing component. The processor 620 may be implemented in hardware, firmware, or a combination of hardware and software. In some implementations, the processor 620 may include one or more processors capable of being programmed to perform one or more operations or processes described elsewhere herein.

The memory 630 may include volatile and/or nonvolatile memory. For example, the memory 630 may include random access memory (RAM), read only memory (ROM), a hard disk drive, and/or another type of memory (e.g., a flash memory, a magnetic memory, and/or an optical memory). The memory 630 may include internal memory (e.g., RAM, ROM, or a hard disk drive) and/or removable memory (e.g., removable via a universal serial bus connection). The memory 630 may be a non-transitory computer-readable medium. The memory 630 may store information, one or more instructions, and/or software (e.g., one or more software applications) related to the operation of the device 600. In some implementations, the memory 630 may include one or more memories that are coupled (e.g., communicatively coupled) to one or more processors (e.g., processor 620), such as via the bus 610. Communicative coupling between a processor 620 and a memory 630 may enable the processor 620 to read and/or process information stored in the memory 630 and/or to store information in the memory 630.

The input component 640 may enable the device 600 to receive input, such as user input and/or sensed input. For example, the input component 640 may include a touch screen, a keyboard, a keypad, a mouse, a button, a microphone, a switch, a sensor, a global positioning system sensor, a global navigation satellite system sensor, an accelerometer, a gyroscope, and/or an actuator. The output component 650 may enable the device 600 to provide output, such as via a display, a speaker, and/or a light-emitting diode. The communication component 660 may enable the device 600 to communicate with other devices via a wired connection and/or a wireless connection. For example, the communication component 660 may include a receiver, a transmitter, a transceiver, a modem, a network interface card, and/or an antenna.

The device 600 may perform one or more operations or processes described herein. For example, a non-transitory computer-readable medium (e.g., memory 630) may store a set of instructions (e.g., one or more instructions or code) for execution by the processor 620. The processor 620 may execute the set of instructions to perform one or more operations or processes described herein. In some implementations, execution of the set of instructions, by one or more processors 620, causes the one or more processors 620 and/or the device 600 to perform one or more operations or processes described herein. In some implementations, hardwired circuitry may be used instead of or in combination with the instructions to perform one or more operations or processes described herein. Additionally, or alternatively, the processor 620 may be configured to perform one or more operations or processes described herein. Thus, implementations described herein are not limited to any specific combination of hardware circuitry and software.

The number and arrangement of components shown in FIG. 6 are provided as an example. The device 600 may include additional components, fewer components, different components, or differently arranged components than those shown in FIG. 6. Additionally, or alternatively, a set of components (e.g., one or more components) of the device 600 may perform one or more functions described as being performed by another set of components of the device 600.

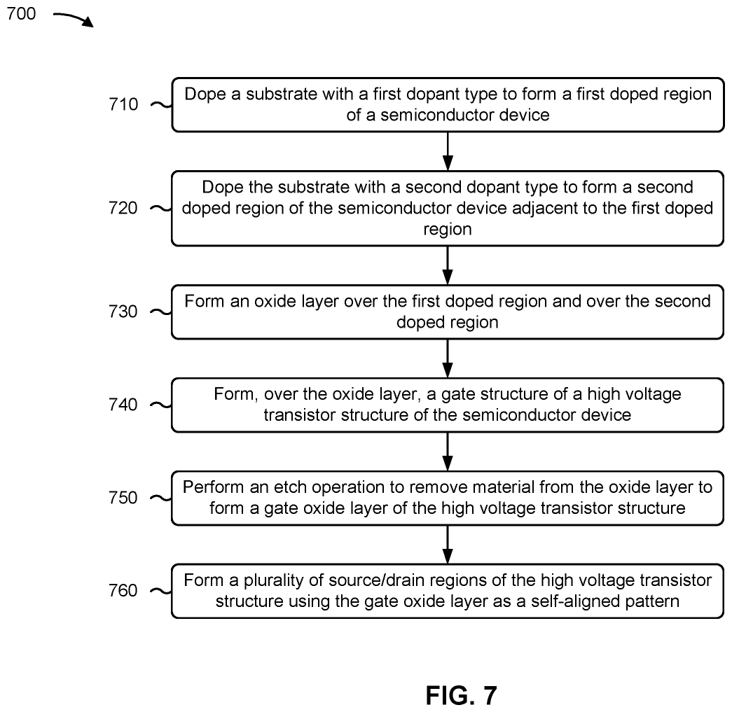

FIG. 7 is a flowchart of an example process 700 associated with forming a semiconductor device described herein. In some implementations, one or more process blocks of FIG. 7 are performed by one or more semiconductor processing tools (e.g., one or more of the semiconductor processing tools 102-114). Additionally, or alternatively, one or more process blocks of FIG. 7 may be performed by one or more components of device 600, such as processor 620, memory 630, input component 640, output component 650, and/or communication component 660.

As shown in FIG. 7, process 700 may include doping a substrate with a first dopant type to form a first doped region of a semiconductor device (block 710). For example, one or more of the semiconductor processing tools 102-114 may dope a substrate 208 with a first dopant type to form a first doped region (e.g., a p-well region 304) of a semiconductor device 200, as described herein.

As further shown in FIG. 7, process 700 may include doping the substrate with a second dopant type to form a second doped region of the semiconductor device adjacent to the first doped region (block 720). For example, one or more of the semiconductor processing tools 102-114 may dope the substrate 208 with a second dopant type to form a second doped region (e.g., an NLDD region 306a, an NLDD region 306b) of the semiconductor device 200 adjacent to the first doped region, as described herein.

As further shown in FIG. 7, process 700 may include forming an oxide layer over the first doped region and over the second doped region (block 730). For example, one or more of the semiconductor processing tools 102-114 may form an oxide layer 522 over the first doped region and over the second doped region, as described herein.

As further shown in FIG. 7, process 700 may include forming, over the oxide layer, a gate structure of a high voltage transistor structure of the semiconductor device (block 740). For example, one or more of the semiconductor processing tools 102-114 may form, over the oxide layer 522, a gate structure 224 of a high voltage transistor structure 212 of the semiconductor device 200, as described herein.

As further shown in FIG. 7, process 700 may include performing an etch operation to remove material from the oxide layer to form a gate oxide layer of the high voltage transistor structure (block 750). For example, one or more of the semiconductor processing tools 102-114 may perform an etch operation to remove material from the oxide layer 522 to form a gate oxide layer 226 of the high voltage transistor structure 212, as described herein. In some implementations, the etch operation results in a portion (e.g., a portion 226b, a portion 226c) of the gate oxide layer 226 extending laterally outward from the gate structure 224.

As further shown in FIG. 7, process 700 may include forming a plurality of source/drain regions of the high voltage transistor structure using the gate oxide layer as a self-aligned pattern (block 760). For example, one or more of the semiconductor processing tools 102-114 may form a plurality of source/drain regions (e.g., a source/drain region 222a, a source/drain region 222b) of the high voltage transistor structure 212 using the gate oxide layer 226 as a self-aligned pattern, as described herein.

Process 700 may include additional implementations, such as any single implementation or any combination of implementations described below and/or in connection with one or more other processes described elsewhere herein.

In a first implementation, forming the plurality of source/drain regions includes doping the substrate 208 using the gate oxide layer 226 as a self-aligned implantation mask.

In a second implementation, alone or in combination with the first implementation, performing the etch operation to remove the material from the oxide layer 522 includes performing the etch operation such that gate oxide layer 226 extends laterally outward from the gate structure 224 by a distance (e.g., a dimension D2) that satisfies a threshold distance.

In a third implementation, alone or in combination with one or more of the first and second implementations, the threshold distance is included in a range of approximately 0.014 microns to approximately 0.05 microns.

In a fourth implementation, alone or in combination with one or more of the first through third implementations, the threshold distance is based on at least one of a gate-to-drain spacing parameter for the high voltage transistor structure 212, a drain voltage of the high voltage transistor structure 212, or a gate voltage of the high voltage transistor structure 212.

In a fifth implementation, alone or in combination with one or more of the first through fourth implementations, the threshold distance is based on a gate induced drain leakage parameter for the high voltage transistor structure 212.

In a sixth implementation, alone or in combination with one or more of the first through fifth implementations, process 700 includes performing a single sidewall spacer formation process to form a sidewall spacer 308 on a sidewall of the gate structure 224 prior to performing the etch operation.

In a seventh implementation, alone or in combination with one or more of the first through sixth implementations, the etch operation results in the portion of the gate oxide layer 226 extending laterally outward from the sidewall spacer 308.

In an eighth implementation, alone or in combination with one or more of the first through seventh implementations, performing the single sidewall spacer formation process comprises performing the single sidewall spacer formation process to form the sidewall spacer on the sidewall of the gate structure and to form another sidewall spacer on another gate structure of a low voltage finFET structure (e.g., a low voltage transistor structure 210) of the semiconductor device 200.

Although FIG. 7 shows example blocks of process 700, in some implementations, process 700 includes additional blocks, fewer blocks, different blocks, or differently arranged blocks than those depicted in FIG. 7. Additionally, or alternatively, two or more of the blocks of process 700 may be performed in parallel.

In this way, a high voltage transistor may include a plurality of source/drain regions, a gate structure, and a gate oxide layer that enables the gate structure to selectively control a channel region between the source/drain regions. The gate oxide layer may extend laterally outward toward one or more of the plurality of source/drain regions such that at least a portion of the gate oxide layer is not under the gate structure. The gate oxide layer extending laterally outward from under the gate structure enables the gate oxide layer to be used as a self-aligned structure for forming the source/drain regions of the high voltage transistor. In particular, the gate oxide layer extending laterally outward from under the gate structure enables the gate oxide layer to be used to form the source/drain regions at a greater spacing from the gate structure than if the gate oxide layer extending were fully contained within a perimeter of the gate structure. This results in less depletion region encroachment onto the source/drain regions and, therefore, reduced (or no) GIDL in the high voltage transistor than if the gate oxide layer extending were fully contained within a perimeter of the gate structure. The reduced GIDL in the high voltage transistor may reduce stand-by power consumption of the high voltage transistor and/or may reduce heat dissipation in the high voltage transistor, which may increase the operational lifespan of the high voltage transistor.

As described in greater detail above, some implementations described herein provide a semiconductor device. The semiconductor device includes a first doped region, comprising a first dopant type, in a substrate of the semiconductor device. The semiconductor device includes a second doped region, comprising a second dopant type, in the substrate and adjacent to the first doped region. The semiconductor device includes a first source/drain region, of a high voltage transistor structure included in the semiconductor device, comprising the second dopant type in the substrate. The semiconductor device includes a second source/drain region, of the high voltage transistor structure, comprising the second dopant type in the substrate and on the second doped region. The semiconductor device includes a gate structure, of the high voltage transistor structure, between the first source/drain region and the second source/drain region. The semiconductor device includes a gate oxide layer, of the high voltage transistor structure, between the first source/drain region and the second source/drain region, where a first portion of the gate oxide layer is under the gate structure and between the gate structure and the substrate, and where a second portion of the gate oxide layer extends laterally outward past the gate structure and is between the second source/drain region and the first portion of the gate oxide layer.

As described in greater detail above, some implementations described herein provide a method. The method includes doping a substrate with a first dopant type to form a first doped region of a semiconductor device. The method includes doping the substrate with a second dopant type to form a second doped region of the semiconductor device adjacent to the first doped region. The method includes forming an oxide layer over the first doped region and over the second doped region. The method includes forming, over the oxide layer, a gate structure of a high voltage transistor structure of the semiconductor device. The method includes performing an etch operation to remove material from the oxide layer to form a gate oxide layer of the high voltage transistor structure, where the etch operation results in a portion of the gate oxide layer extending laterally outward from the gate structure. The method includes forming a plurality of source/drain regions of the high voltage transistor structure using the gate oxide layer as a self-aligned pattern.

As described in greater detail above, some implementations described herein provide a semiconductor device. The semiconductor device includes a substrate. The semiconductor device includes a low voltage device region. The semiconductor device includes a high voltage device region. The semiconductor device includes an isolation region between the low voltage device region and the high voltage device region, where the low voltage device region includes one or more low voltage finFET structures, where the high voltage device region includes a high voltage transistor structure, and where the high voltage transistor structure includes a first source/drain region, a second source/drain region, a gate structure between the first source/drain region and the second source/drain region, a gate oxide layer, between the first source/drain region and the second source/drain region, where a first portion of the gate oxide layer is under the gate structure and between the gate structure and the substrate, and where a second portion of the gate oxide layer extends laterally outward past the gate structure and is between the first source/drain region and the first portion of the gate oxide layer, and where a third portion of the gate oxide layer extends laterally outward past the gate structure and is between the second source/drain region and the first portion of the gate oxide layer.

As used herein, “satisfying a threshold” may, depending on the context, refer to a value being greater than the threshold, greater than or equal to the threshold, less than the threshold, less than or equal to the threshold, equal to the threshold, not equal to the threshold, or the like.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor device, comprising:
a first doped region, comprising a first dopant type, in a substrate of the semiconductor device;
a second doped region, comprising a second dopant type, in the substrate and adjacent to the first doped region;
a first source/drain region, of a high voltage transistor structure included in the semiconductor device, comprising the second dopant type in the substrate;
a second source/drain region, of the high voltage transistor structure, comprising the second dopant type in the substrate and on the second doped region;
a gate structure, of the high voltage transistor structure, between the first source/drain region and the second source/drain region; and
a gate oxide layer, of the high voltage transistor structure, between the first source/drain region and the second source/drain region,
wherein a first portion of the gate oxide layer is under the gate structure and between the gate structure and the substrate, and
wherein a second portion of the gate oxide layer extends laterally outward past the gate structure and is between the second source/drain region and the first portion of the gate oxide layer.

2. The semiconductor device of claim 1, further comprising:
a sidewall spacer on a sidewall of the gate structure facing the second source/drain region,
wherein the second portion of the gate oxide layer extends laterally outward past the sidewall spacer.

3. The semiconductor device of claim 2, wherein the sidewall spacer comprises a single-layer sidewall spacer.

4. The semiconductor device of claim 1, wherein the second portion of the gate oxide layer is included at least partially on a portion of the second doped region.

5. The semiconductor device of claim 4, wherein the first portion of the gate oxide layer is at least partially on the second doped region.

6. The semiconductor device of claim 1, wherein the gate oxide layer comprises a third portion that extends laterally outward past the gate structure and is between the first source/drain region and the first portion of the gate oxide layer.

7. The semiconductor device of claim 6, further comprising:
a third doped region, comprising the second dopant type, in the substrate,
wherein the first source/drain region is included on the third doped region, and
wherein the third portion of the gate oxide layer is included on a portion of the third doped region.

8. A method, comprising:
doping a substrate with a first dopant type to form a first doped region of a semiconductor device;
doping the substrate with a second dopant type to form a second doped region of the semiconductor device adjacent to the first doped region;
forming an oxide layer over the first doped region and over the second doped region;
forming, over the oxide layer, a gate structure of a high voltage transistor structure of the semiconductor device;
performing an etch operation to remove material from the oxide layer to form a gate oxide layer of the high voltage transistor structure,
wherein the etch operation results in a portion of the gate oxide layer extending laterally outward from the gate structure; and
forming a plurality of source/drain regions of the high voltage transistor structure using the gate oxide layer as a self-aligned pattern.

9. The method of claim 8, wherein forming the plurality of source/drain regions comprises:
doping the substrate using the gate oxide layer as a self-aligned implantation mask.

10. The method of claim 8, wherein performing the etch operation to remove the material from the oxide layer comprises:
performing the etch operation such that gate oxide layer extends laterally outward from the gate structure by a distance that satisfies a threshold distance.

11. The method of claim 10, wherein the threshold distance is included in a range of approximately 0.014 microns to approximately 0.05 microns.

12. The method of claim 10, wherein the threshold distance is based on at least one of:
a gate-to-drain spacing parameter for the high voltage transistor structure,
a drain voltage of the high voltage transistor structure, or
a gate voltage of the high voltage transistor structure.

13. The method of claim 10, wherein the threshold distance is based on a gate induced drain leakage parameter for the high voltage transistor structure.

14. The method of claim 8, further comprising:
performing a single sidewall spacer formation process to form a sidewall spacer (310) on a sidewall of the gate structure prior to performing the etch operation.

15. The method of claim 14, wherein the etch operation results in the portion of the gate oxide layer extending laterally outward from the sidewall spacer.

16. The method of claim 14, wherein performing the single sidewall spacer formation process comprises:
performing the single sidewall spacer formation process to form the sidewall spacer on the sidewall of the gate structure and to form another sidewall spacer on another gate structure of a low voltage fin field effect transistor (finFET) structure of the semiconductor device.

17. A semiconductor device, comprising:
a substrate;
a low voltage device region;
a high voltage device region; and
an isolation region between the low voltage device region and the high voltage device region,
wherein the low voltage device region includes one or more low voltage fin field effect transistor (finFET) structures,
wherein the high voltage device region includes a high voltage transistor structure, and
wherein the high voltage transistor structure comprises:
a first source/drain region;
a second source/drain region;
a gate structure between the first source/drain region and the second source/drain region; and
a gate oxide layer, between the first source/drain region and the second source/drain region,
wherein a first portion of the gate oxide layer is under the gate structure and between the gate structure and the substrate, and
wherein a second portion of the gate oxide layer extends laterally outward past the gate structure and is between the first source/drain region and the first portion of the gate oxide layer, and
wherein a third portion of the gate oxide layer extends laterally outward past the gate structure and is between the second source/drain region and the first portion of the gate oxide layer.

18. The semiconductor device of claim 17, wherein a low voltage finFET structure of the one or more low voltage finFET structures comprises:
a fin structure; and
a low voltage gate structure that wraps around three sides of the fin structure,
wherein a portion of the low voltage gate structure on the fin structure, and the gate structure of the high voltage transistor structure, are located at approximately a same height in the semiconductor device.

19. The semiconductor device of claim 17, wherein the high voltage transistor structure further comprises:
a first single-layer sidewall spacer on a first sidewall of the gate structure facing the first source/drain region,
wherein the second portion of the gate oxide layer extends laterally outward past the first single-layer sidewall spacer; and
a second single-layer sidewall spacer on a second sidewall of the gate structure facing the second source/drain region,
wherein the third portion of the gate oxide layer extends laterally outward past the second single-layer sidewall spacer.

20. The semiconductor device of claim 17, wherein the high voltage transistor structure further comprises:
a sidewall spacer (308) on a sidewall of the gate structure,
wherein a width of the second portion of the gate oxide layer is greater relative to a thickness of the sidewall spacer.
